(19) United States
(12) Patent Application Publication
(10) Pub. No.: US 2019/0189561 A1
(43) Pub. Date: Jun. 20, 2019

(54) SEMICONDUCTOR DEVICE AND METHOD WITH MULTIPLE REDISTRIBUTION LAYER AND FINE LINE CAPABILITY

(71) Applicant: Chip Solutions, LLC, Phoenix, AZ (US)

(72) Inventor: Sukianto Rusli, Phoenix, AZ (US)

(21) Appl. No.: 16/278,972

(22) Filed: Feb. 19, 2019

Related U.S. Application Data
(63) Continuation-in-part of application No. 15/705,567, filed on Sep. 15, 2017.
Application No. 15/705,567 is a continuation-in-part of application No. 15/405,700, filed on Jan. 13, 2017, now Pat. No. 9,922,949.
Application No. 15/405,700 is a continuation-in-part of application No. 15/211,290, filed on Jul. 15, 2016, now Pat. No. 9,941,146.
Application No. 15/211,290 is a continuation-in-part of application No. 15/211,384, filed on Jul. 15, 2016.
Application No. 15/211,384 is a continuation-in-part of application No. 15/211,481, filed on Jul. 15, 2016.
Application No. 15/211,481 is a continuation-in-part of application No. 15/211,631, filed on Jul. 15, 2016, now Pat. No. 9,847,244.
(60) Provisional application No. 62/388,023, filed on Jan. 14, 2016.
(60) Provisional application No. 62/231,814, filed on Jul. 15, 2015.
(60) Provisional application No. 62/388,023, filed on Jan. 14, 2016.
(60) Provisional application No. 62/231,814, filed on Jul. 15, 2015.
(60) Provisional application No. 62/388,023, filed on Jan. 14, 2016.
(60) Provisional application No. 62/231,814, filed on Jul. 15, 2015.
(60) Provisional application No. 62/388,023, filed on Jan. 14, 2016.
(60) Provisional application No. 62/231,814, filed on Jul. 15, 2015.

(51) Int. Cl. H01L 23/538; H01L 23/532; H01L 23/31; H01L 23/528; H01L 23/522; H01L 21/56; H01L 21/768; H01L 21/3213; H01L 23/00

(52) U.S. Cl. CPC H01L 23/5383; H01L 2224/73253; H01L 23/3128; H01L 23/5283; H01L 23/5226; H01L 21/566; H01L 21/76802; H01L 21/3213; H01L 24/09; H01L 24/17; H01L 24/32; H01L 24/73; H01L 2224/0231; H01L 2224/02373; H01L 2224/02381; H01L 2924/15311; H01L 23/53228

(57) ABSTRACT

A semiconductor device includes a semiconductor die and a substrate having a first surface and a second surface. The semiconductor die is attached to the second surface. The substrate includes a layer of insulative material and an embedded conductive circuit in the layer of insulative material. The embedded conductive circuit includes an etched layer of a conductive material. The etched layer of the conductive material is located on the first surface of the substrate. The etched layer of the conductive material is made of a first metallic material and the embedded conductive circuit is made of a second metallic material that is different than the first metallic material.

### CROSS-REFERENCE TO RELATED APPLICATIONS

This application is a continuation-in-part of U.S. Nonprovisional application Ser. No. 15/705,567, filed Sep. 15, 2017, which is a continuation-in-part of U.S. Nonprovisional application Ser. No. 15/405,700, filed Jan. 13, 2017, now U.S. Pat. No. 9,922,949, which claims priority to U.S. Nonprovisional application Ser. No. 15/211,631, filed Jul. 15, 2016, now U.S. Pat. No. 9,847,244; U.S. Nonprovisional application Ser. No. 15/211,290, filed Jul. 15, 2016, now U.S. Pat. No. 9,941,146; U.S. Nonprovisional application Ser. No. 15/211,384, filed Jul. 15, 2016; and U.S. Nonprovisional application Ser. No. 15/211,481, filed on Jul. 15, 2016, each of which claim priority to U.S. Provisional Patent Application No. 62/388,023 filed Jan. 14, 2016 and U.S. Provisional Patent Application No. 62/231,814 filed Jul. 15, 2015; each of which is incorporated herein by reference in its entirety.

### FIELD OF THE TECHNOLOGY

The subject matter disclosed herein generally relates to the fabrication of semiconductor devices. More particularly, the subject matter relates to a semiconductor device having an etched conductive layer.

### BACKGROUND

In known wafer level packaging (WLP) processes, a carrier wafer may be laminated to dicing tape and known good die are placed face down. The wafer may then be compression molded to encapsulate it and then the wafer carrier and tape may be removed. The molding compound may then be used to carry the fan-out area and to protect the chip backside. Redistribution layers may be created on the exposed die faces, the I/O may be rerouted, solder balls may be placed, and the die may be singulated. In other conventional non wafer level processes, methods include slicing the wafer into individual die and then packaging them.

Few semiconductor packaging and assembly techniques currently utilize embedded conductive circuits. When utilized, most embedded circuit implementations include a conductive circuit layer that is patterned onto a surface of a metal core base layer. A dielectric material is then layered onto the conductive circuit followed by the application of a thin layer of conductive layer. This foil is then etched to complete the circuit.

However, there are various limitations inherent in these known processes. Therefore, improved layering structures for semiconductor devices would be well received in the art.

### SUMMARY

According to one embodiment, a semiconductor device comprises a semiconductor die and a substrate having a first surface and a second surface, wherein the semiconductor die is attached to the second surface, the substrate comprising a layer of insulative material and an embedded conductive circuit in the layer of insulative material, wherein the embedded conductive circuit includes an etched layer of a conductive material, the etched layer of the conductive material located on the first surface of the substrate, and wherein the etched layer of the conductive material is made of a first metallic material and the embedded conductive circuit is made of a second metallic material that is different than the first metallic material.

According to another embodiment, a method of making a semiconductor device comprises patterning a conductive circuit on a conductive layer; applying an insulative material over the conductive circuit to create a substrate having a first surface and a second surface, wherein the conductive layer is located on the first surface; attaching a semiconductor die to the second surface of the substrate; and etching the conductive layer, wherein the conductive layer is made of a first metallic material and the conductive circuit is made of a second metallic material that is different than the first metallic material.

According to another embodiment, a semiconductor device comprising a first substrate including a layer of insulative material and a first embedded conductive circuit layer in the layer of insulative material; a second substrate including a second layer of insulative material and a second conductive circuit layer in the second layer of insulative material; and an encapsulated semiconductor die located between the first substrate and the second substrate; a layer of insulative material located between the encapsulated semiconductor die and the second substrate, wherein the first substrate and second substrate are interconnected.

The present invention advantageously provides a simple method and associated system for forming a semiconductor package.

### BRIEF DESCRIPTION OF THE DRAWINGS

The subject matter which is regarded as the invention is particularly pointed out and distinctly claimed in the claims included at the conclusion of this specification. The foregoing and other features and advantages of the invention are apparent from the following detailed description taken in conjunction with the accompanying drawings in which:

FIG. 1 depicts a side cutaway view of a step of a fabrication process according to one embodiment;

FIG. 2 depicts a side cutaway view of another step of the fabrication process of FIG. 1 according to one embodiment;

FIG. 3 depicts a side cutaway view of another step of the fabrication process of FIGS. 1-2 according to one embodiment;

FIG. 4 depicts a side cutaway view of another step of the fabrication process of FIGS. 1-3 according to one embodiment;

FIG. 5 depicts a side cutaway view of another step of the fabrication process of FIGS. 1-4 according to one embodiment;

FIG. 6 depicts a side cutaway view of another step of the fabrication process of FIGS. 1-5 according to one embodiment;

FIG. 7 depicts a side cutaway view of another step of the fabrication process of FIGS. 1-6 according to one embodiment;

FIG. 8 depicts a side cutaway view of another step of the fabrication process of FIGS. 1-7 according to one embodiment;

FIG. 9 depicts a side cutaway view of another step of the fabrication process of FIGS. 1-8 according to one embodiment;

FIG. 10 depicts a side cutaway view of another step of the fabrication process of FIGS. 1-9 according to one embodiment;

FIG. 11 depicts a side cutaway view of another step of the fabrication process of FIGS. 1-10 according to one embodiment;

FIG. 12 depicts a side cutaway view of another step of the fabrication process of FIGS. 1-11 according to one embodiment;

FIG. 13 depicts a side cutaway view of another step of a fabrication process according to one embodiment;

FIG. 14 depicts a side cutaway view of another step of the fabrication process of FIGS. 13 according to one embodiment;

FIG. 15 depicts a side cutaway view of another step of the fabrication process of FIGS. 13-14 according to one embodiment;

FIG. 16 depicts a side cutaway view of another step of the fabrication process of FIGS. 13-15 according to one embodiment;

FIG. 17 depicts a side cutaway view of an option for a build-up of layers in a fabrication process according to one embodiment;

FIG. 18 depicts an exploded view of layers of a carrier structure in accordance with one embodiment;

FIG. 19 depicts an exploded view of layers of another carrier structure in accordance with one embodiment;

FIG. 20 depicts a UV release film in accordance with one embodiment;

FIG. 21 depicts a thermal release film in accordance with one embodiment;

FIG. 22 depicts the thermal release film of FIG. 21 after activation in accordance with one embodiment;

FIG. 23a depicts a side cutaway view of a step of a fabrication process in accordance with one embodiment;

FIG. 23b depicts a side cutaway view of another step of the fabrication process of FIG. 23a in accordance with one embodiment;

FIG. 23c depicts a side cutaway view of another step of the fabrication process of FIGS. 23a-23b in accordance with one embodiment;

FIG. 23d depicts a side cutaway view of another step of the fabrication process of FIGS. 23a-23c in accordance with one embodiment;

FIG. 24 depicts a side cutaway view of a system in package structure in accordance with one embodiment;

FIG. 25 depicts a thermal adhesive tape in accordance with one embodiment;

FIG. 26 depicts a double mold layering structure in accordance with one embodiment;

FIG. 27 depicts a interconnect joint layering structure in accordance with one embodiment;

FIG. 28 depicts another interconnect joint layering structure in accordance with one embodiment;

FIG. 29 depicts an exploded view of layers of another carrier structure in accordance with one embodiment;

FIG. 30 depicts an exploded view of layers of another carrier structure in accordance with one embodiment;

FIG. 31 depicts an embodiment of a multiple step release process for a releasable carrier in accordance with one embodiment;

FIG. 32 depicts another embodiment of a multiple step release process for a releasable carrier in accordance with one embodiment;

FIG. 33 depicts an alternative embodiment of a carrier structure whereby multiple semiconductor carriers are used, in accordance with one embodiment;

FIG. 34a illustrates a first alternative embodiment for the first portion of the carrier structure of FIG. 33, in accordance with one embodiment;

FIG. 34b illustrates a second alternative embodiment for the first portion of the carrier structure of FIG. 33 in accordance with one embodiment;

FIG. 35a illustrates an alternative embodiment for the second portion of the carrier structure of FIG. 33 in accordance with one embodiment;

FIG. 35b illustrates an alternative embodiment for the additional carrier 800c of the carrier structure 800 of FIG. 33 in accordance with one embodiment;

FIGS. 36a-36m illustrate a fabrication process for the creation or fabrication of the carrier structure of FIG. 33 in accordance with one embodiment;

FIGS. 37a-37c illustrate a laser singulation process for generating multiple semiconductor packages in accordance with one embodiment;

FIG. 38 illustrates the operational test step of FIG. 36g in accordance with one embodiment;

FIG. 39 illustrates an alternative test step with respect to the process of FIG. 38 in accordance with one embodiment;

FIG. 40a illustrates a first flow diagram associated with a carrier structure panel to panel to panel (PPP) format in accordance with one embodiment;

FIG. 40b illustrates a second flow diagram associated with a carrier structure panel to strip to strip (PSS) format in accordance with one embodiment;

FIG. 40C illustrates a third flow diagram associated with a carrier structure panel to strip to panel (PSP) format in accordance with one embodiment;

FIGS. 41A and 41B illustrate an embodiment of a second releasable chip carrier in accordance with one embodiment;

FIG. 42A depicts a side cutaway view of a step of a fabrication process according to one embodiment;

FIG. 42B depicts a side cutaway view of another step of the fabrication process of FIG. 42A according to one embodiment;

FIG. 42C depicts a side cutaway view of another step of the fabrication process of FIG. 42A-42B according to one embodiment;

FIG. 42D depicts a side cutaway view of another step of the fabrication process of FIG. 42A-42C according to one embodiment;

FIG. 42E depicts a side cutaway view of another step of the fabrication process of FIG. 42A-42D according to one embodiment;

FIG. 42F depicts a side cutaway view of another step of the fabrication process of FIG. 42A-42E according to one embodiment;

FIG. 42G depicts a side cutaway view of another step of the fabrication process of FIG. 42A-42F according to one embodiment;

FIG. 42H depicts a side cutaway view of another step of the fabrication process of FIG. 42A-42G according to one embodiment;

FIG. 42I depicts a side cutaway view of another step of the fabrication process of FIG. 42A-42H according to one embodiment;

FIG. 42J depicts a side cutaway view of another step of the fabrication process of FIG. 42A-42I according to one embodiment;

FIG. 42K depicts a side cutaway view of another step of the fabrication process of FIG. 42A-42J according to one embodiment;

FIG. 42L depicts a side cutaway view of another step of the fabrication process of FIG. 42A-42K according to one embodiment;

FIG. 43 depicts a side cutaway view of a step of a fabrication process according to one embodiment;

FIG. 44 depicts an exploded view of the releasable carrier shown in FIG. 42A;

FIG. 45 depicts an exploded view of the releasable carrier shown in FIG. 43;

FIG. 46 depicts a side cutaway of a step of a fabrication process according to one embodiment.

FIG. 47A depicts a side cutaway view of a step of a fabrication process according to one embodiment;

FIG. 47B depicts a side cutaway view of another step of the fabrication process of FIG. 46A according to one embodiment;

FIG. 47C depicts a side cutaway view of another step of the fabrication process of FIG. 46A-46B according to one embodiment;

FIG. 47D depicts a side cutaway view of another step of the fabrication process of FIG. 46A-46C according to one embodiment;

FIG. 47E depicts a side cutaway view of another step of the fabrication process of FIG. 46A-46D according to one embodiment;

FIG. 47F depicts a side cutaway view of another step of the fabrication process of FIG. 46A-46E according to one embodiment; and

FIG. 47G depicts a side cutaway view of another step of the fabrication process of FIG. 46A-F according to one embodiment.

FIG. 48 depicts a side cutaway view of a semiconductor device in accordance with one embodiment.

### DETAILED DESCRIPTION

A detailed description of the hereinafter-described embodiments of the disclosed apparatus and method are presented herein by way of exemplification and not limitation with reference to the Figures.

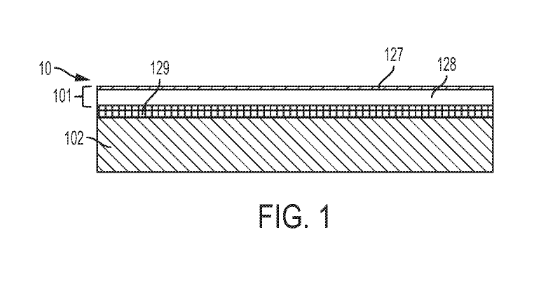

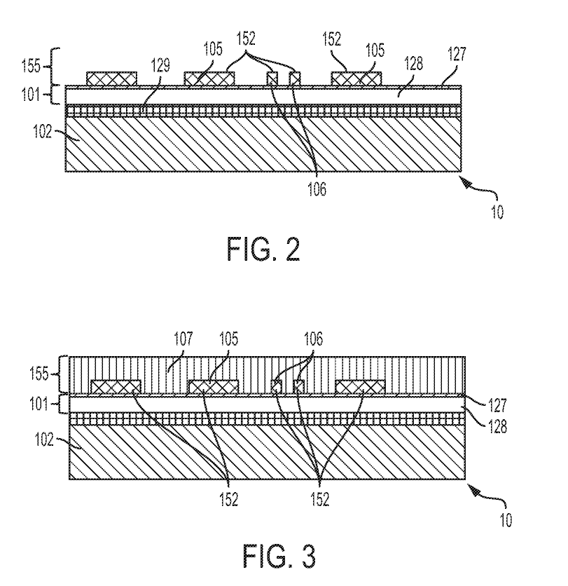

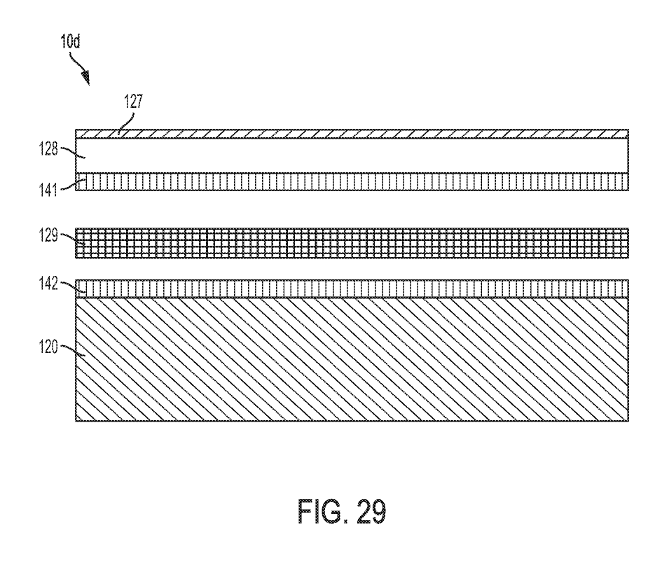

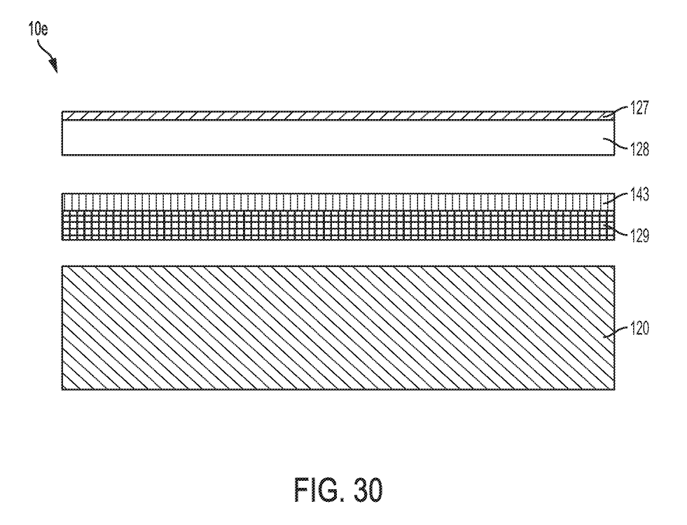

Referring to FIGS. 1-12, a fabrication process for the creation or fabrication of a semiconductor device 100 is shown. The fabrication process is shown in FIG. 1 to include a step of providing a releasable carrier 102 that is attached to conductive layers 101 to create a carrier structure 10. The conductive layers 101 may include a combination of a carrier foil 128 and a thin foil 127. The carrier foil 128 may be a thicker conductive layer and the thin foil 127 may be a thin conductive layer. An adhesive layer 129 may be located between the carrier 102 and the conductive layers 101. Embodiments of the releasable carrier 120 and the conductive layers 101 combination are shown in the exploded views provided by FIGS. 19-20.

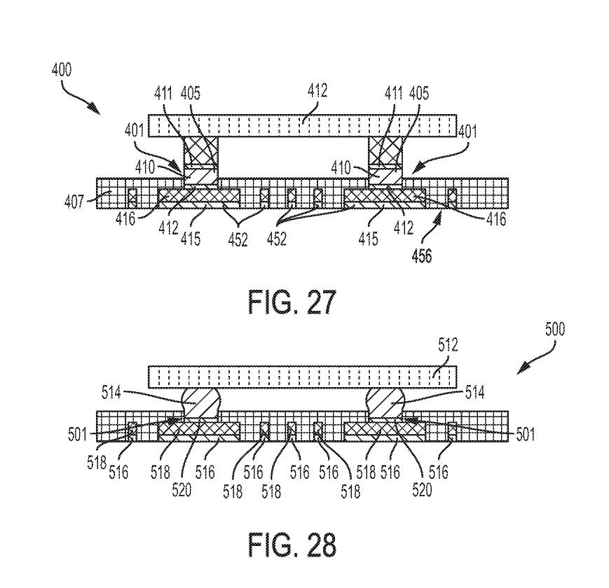

FIG. 18 shows a carrier structure 10a having a releasable carrier 120 that may be a metal or core carrier 120a. FIG. 19 shows a carrier structure 10b having a glass releasable carrier 120b. Glass may be a preferred material for the releasable carrier 120 because it is extremely flat, thermally and dimensionally stable, and has a low coefficient of thermal expansion. However, other materials may have other advantages. The releasable carrier 120 may be a glass carrier, a metal core carrier, a clad core carrier, a laminate carrier, an aluminum carrier, a copper carrier, or a stainless steel carrier, an organic reinforced core carrier a ceramic material or combinations thereof. These carrier materials are exemplary. Further, the releasable carrier 120 may have varying thicknesses and may extend over varying areas. It should be understood that the concepts described herein may be applicable to any panel size format (e.g. 500 mm×500 mm). Further, the releasable carrier 120 may be a made from a material that is dimensionally stable, stiff and flat. These three characteristics may be particularly advantageous during the rest of the described fabrication process. Further, because the releasable carrier 120 may be reused for a second fabrication process after being released in the manner described herein, the releasable carrier 120 may be fashioned in a thicker manner, as the reusability of the releasable carrier 120 may preclude the engineering need to reduce material cost as would be required for one-off carriers.

To create or fabricate the carrier structure 10, the adhesive layer 129 may be applied to one of the releasable carrier 120 or the conductive layers 101 in a first step. The other of the releasable carrier 120 or the conductive layers 101 may then be attached. The adhesive layer 129 may include one or more layers such as a base with adhesive on one or both sides of the base (i.e. a double-sided tape).

As shown in FIG. 18, the adhesive layer 129 may include a thermal sensitive adhesive 131 on one or both sides of a double-sided tape. The thermal sensitive adhesive 131 may be configured to have a reduced adhesive capacity when exposed to high temperatures from, for example, a heat source. This may allow the thermal sensitive adhesive 131 to release when exposed to heat. For example, the activating heat source may be configured to raise the temperature of the thermal sensitive adhesive 131 to a temperature between 150 and 300° C. For example, in one embodiment, the temperature of the thermal activating source may be set to 250° C. with the release temperature of the thermal sensitive adhesive 131 being in the range of 180° C. and 220° C.

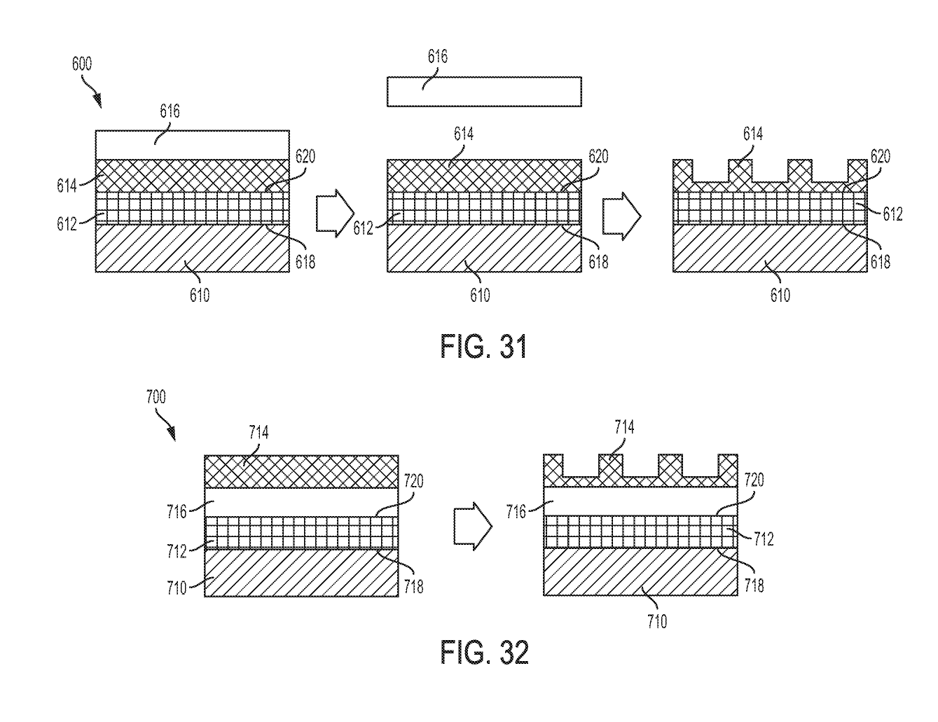

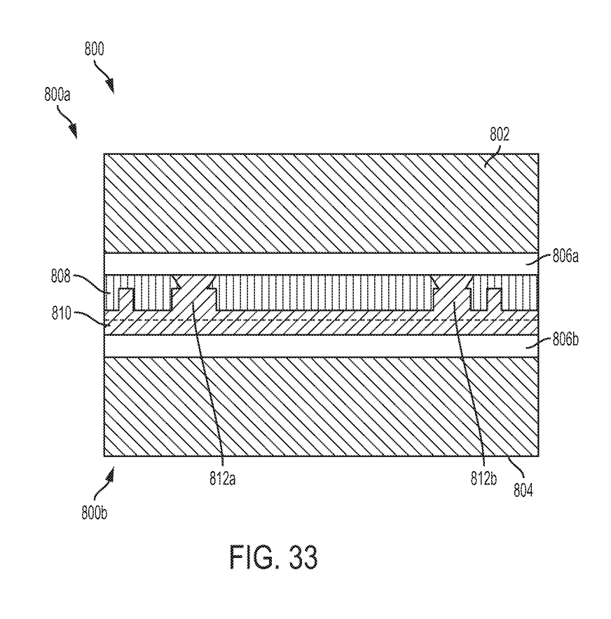

One embodiment of a structure of the thermal sensitive adhesive 131 is shown in FIGS. 21 and 22. FIG. 21 shows the thermal sensitive adhesive 131 prior to activation. FIG. 22 shows the thermal sensitive adhesive 131 after activation. The thermal sensitive adhesive 131 may include a backing layer 131a. A thermal release adhesive layer 131b may be layered above the backing layer 131a. A substrate layer 131c may be attached to the thermal release adhesive layer 131b. The substrate layer 131c may be any particular substrate such a release film liner. Thus, the thermal release adhesive layer 131 may be activated by heat from a heat source to create the release. The thermal release adhesive layer 131b may include expandable molecules that expand when exposed to increased temperatures. Such expansion may reduce the tendency for adhesion of the molecules to provide for the thermal release of the thermal sensitive adhesive 131.

Alternatively, the adhesive layer 129 may include a UV sensitive adhesive 132 on one or each side of a double-sided tape, as shown in FIG. 19. The UV sensitive adhesive 132 may be configured to have a reduced adhesive capacity when exposed to a UV light source. This may allow the UV sensitive adhesive 132 to release when exposed to the UV light source. For example, the UV light activation source (not shown) may be a UV light source generating irradiation energy between 20 mW/cm² and 40 mW/cm². In the embodiment where a UV sensitive adhesive is utilized, it may be particularly advantageous to use a glass material for the releasable carrier 120. The transparent nature of glass may allow the UV sensitive adhesive to be exposed to the UV light activation source through the glass of the releasable carrier 120.

One embodiment of a structure of the UV sensitive adhesive 132 is shown in FIG. 20. The UV sensitive adhesive 132 may include a polyolefin film layer 132a. A UV curing acrylic adhesive layer 132b may be layered above the polyolefin film layer 132a. A polyester film release liner 132c may be layered above the UV curing acrylic adhesive layer 132b. Thus, the UV curing acrylic adhesive layer 132b may be the layer that is activated by the UV source to create the release from the liner layers 132a, 132c. The thickness of the middle UV curing acrylic adhesive layer 132b may be thinner than the liner layers 132a, 132c. In one embodiment, the UV curing acrylic adhesive layer 132b may be 3-10 μm, while the combination of the liner layers 132a, 132c may each be 60-100 μm. In one embodiment, the UV curing acrylic adhesive layer 132b may be 8 μm or 5 μm while the liner layers 132a may be 80 μm.

In other embodiments, the double-sided tape may include two different adhesives, one on each side. For example, the double-sided tape may include a thermal sensitive adhesive on one side and a UV sensitive adhesive on the other. In still another embodiment, the double-sided tape may include a UV sensitive adhesive on one side and a no-release adhesive on the other side. In another embodiment, a pressure sensitive adhesive may be applied to one side of the double-sided tape while the other side includes the UV sensitive adhesive or the thermal sensitive adhesive. It should be understood that different adhesive combinations are contemplated for the double-sided tape in order to accomplish different release circumstances depending on the engineering requirements of a particular process or fabrication.

Attached to the releasable carrier 120 with the adhesive layer 129 are the conductive layers 101. The conductive layers 101 may include both the carrier foil 128 and the thin foil 127. The carrier foil 128 may be releasable from the thin foil 127 by mechanically pulling the carrier foil 128 from the thin foil 127 to expose the thin foil 127. In other embodiments, adhesives or a double-sided tape may be applied between the carrier foil 128 and the thin foil 127 which may release the carrier foil 128 from the thin foil 127 in a manner similar or the same as the releasable carrier 120 releases from the conductive layers 101 with the adhesive layer 129. The carrier foil 128 may be a thicker layer than the thin foil 127. In one embodiment, the carrier foil 128 may be 50 μm-70 μm. In one embodiment, the thin foil 127 may be between 1 μm and 5 μm. However, these thicknesses are exemplary and thicker or thinner layers may be appropriate in some embodiments.

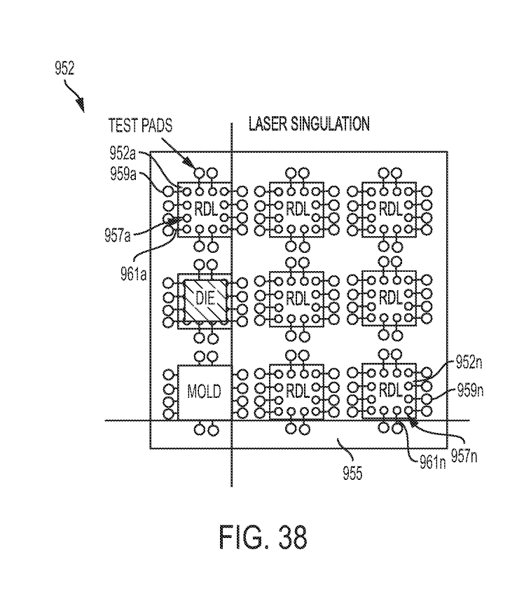

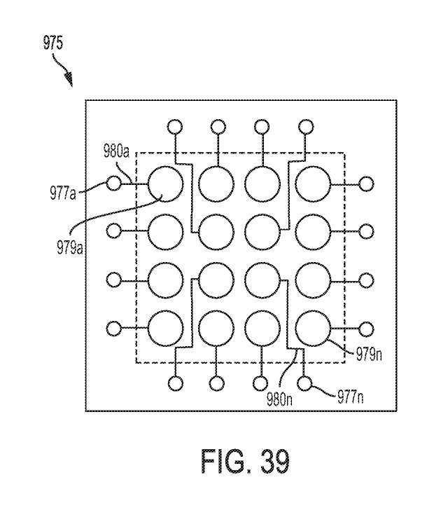

Referring now to FIGS. 29, still another embodiment of a carrier structure 10d is shown whereby the releasable carrier 120 includes a thermal barrier coating 142 applied to the releasable carrier 120 between the releaseable carrier 120 and the adhesive layer 129. The thermal barrier coating 142 may be configured to prevent the loss of adhesion for the adhesive layer 129 as a result of elevated temperatures that might occur in other steps of the assembly processing (e.g. during reflow). Furthermore, FIG. 29 shows that a second barrier release coating 141 is applied to the carrier foil 128 between the carrier foil 128 and the adhesive layer 129. Another barrier release coating (not shown) may be applied to an undersurface of the carrier as well to act as a thermal barrier at this location in the carrier structure. Referring to FIG. 30, another embodiment is shown where a third thermal barrier coating 143 is applied to the top of the adhesive layer 129 between the adhesive layer 129 and the carrier foil 128.

The thermal barrier coatings 141, 142, 143 may be applied as a layer between any release interface in the carrier structure 10. Both sides of the adhesive layer 129 may include a thermal barrier coating. The thermal barrier coatings 141, 142, 143 may be micron size fillers that may be applied to appropriate layers of the carrier structure 10 and more specifically the adhesive layer 129. These filler particles may be hollow ceramic insulative spheres in one embodiment. The thermal barrier coatings 141, 142, 143 may be adjusted to the desired thickness to provide the necessary protection for the layers of the carrier structure 10 and the thermal sensitive adhesive 131 (or the UV, pressure sensitive, or other adhesives described above). The thermal barrier coatings 141, 142, 143 may be applied by various methods such as thermal spray.

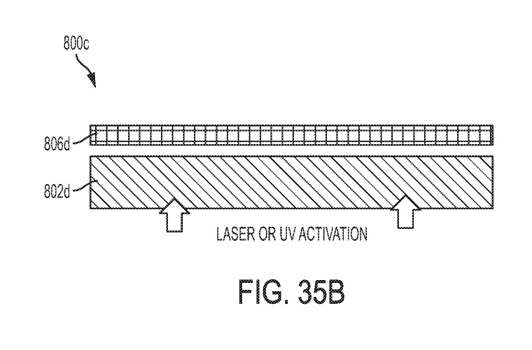

Referring to FIG. 25, it is contemplated that the thermal barrier material may be combined or mixed with an adhesive in a combined adhesive/barrier layer, rather than two separate layers. In this embodiment, a version of the adhesive layer 129 is shown including a double sided tape having a polyester base material layer 129a located between a thermal sensitive adhesive 131 and a pressure sensitive adhesive 150. The pressure sensitive adhesive 150 may include thermal barrier fillers 151 in a combined manner. The thermal barrier fillers 151 may be mixed with the pressure sensitive adhesive 150. The thermal barrier fillers 151 may be formulated in the form of hollow ceramic spheres in one embodiment that may be configured to act as an insulator. These thermal barrier fillers 151 may be mixed with any of the adhesives (thermal, UV, pressure) in this manner. In this version the double sided tape further includes a first release liner 129b layered on top of the thermal release adhesive 131 and a second release liner 129c layered below the pressure sensitive adhesive 150. These release liners 129b, 129c may be utilized on any embodiment of the carrier structure 10 described herein and may be removed when applying the double sided tape to the carrier structure 10 during the fashioning of the carrier structure 10 prior to a circuit or semiconductor device fabrication process.

Whatever the embodiment, the releasable carrier 120 may be configured to release from the rest of the carrier structure 10 from the conductive layers 101 when exposed to an activating source, such as a UV source or a heat source as described herein above. The activating source may require no physical contact with the releasable carrier 120 to activate the adhesive layer 129 and release the releasable carrier in a manner consistent with that described herein. Further, the activating source may be a non-mechanical activating source and may create a clean release such that the releasable carrier 120 is reusable for additional fabrication processes. Further, the releasable carrier 120 may include three release points: a first release point between the thin foil 127 and the carrier foil 128; a second release point between the carrier foil 128 and the adhesive layer 129 or releasable tape; and a third between the releasable carrier 120 and the adhesive layer 129 or releasable tape.

It should further be understood that the carrier structures described herein may be used on any panel size or format, from wafer to large panel processes. Further the carrier structures described herein may be used on standard build up processes or sputtering methods. Further, the carrier structures may expand fan out wafer level packaging to sizes beyond the current 12″ diameter standard. Moreover, the carrier structures may be capable for any panel size format including rectangular, square or circular. Further, the carrier structures and accompanying methods described herein may be compatible with wirebond, flip chip, integrated passive devices, conventional passives and multi-die structures.

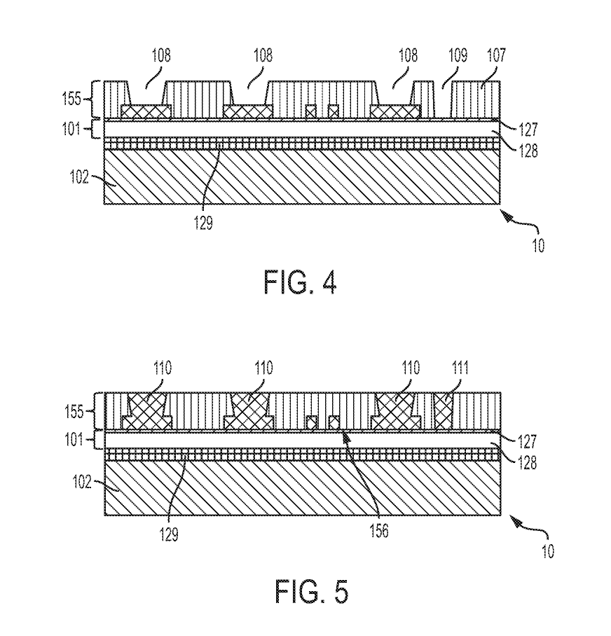

Referring back to the process of FIGS. 1-12, FIG. 2 shows another step in the fabrication process. Once the releasable carrier 120 has been provided (with or without the openings 103), a substrate 155 may begin to be built upon the releasable carrier 120, as shown in FIGS. 3-6. In the first step of building this substrate 155, shown in FIG. 3, a conductive circuit 152 may be applied. The conductive circuit 152 may include a plurality of die attach pads 105 and a plurality of traces 106. The die attach pads 105 and the traces 106 may each be plated conductive elements. The conductive circuit 152 may be applied atop the layer of the thin foil 127 while the releasable carrier 120 remains attached. The conductive circuit 152 is not limited to these elements and may include any appropriate conductive elements, portions or the like. The conductive circuit 152 may be a redistribution layer (RDL) and may be formed with RDL patterning with semi-additive plating.

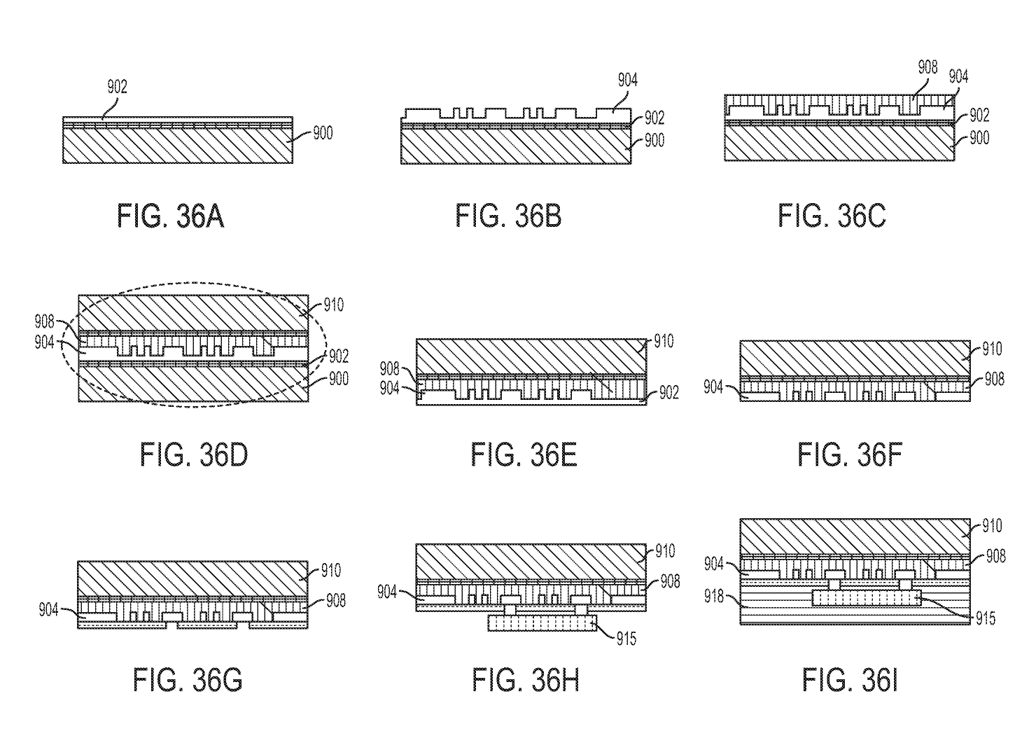

Referring now to FIG. 3, another step of the fabrication process is shown. The fourth step includes laminating the conductive circuit 152 with an insulative material 107 to encapsulate the conductive circuit 152. The insulative material 107 may be a photo-imageable dielectric (PID) in one embodiment. In others, the insulative material 107 may be an ABF film. In still other embodiments, as described herein below with respect to FIG. 26, the insulative material 107 may be a mold compound. The insulative material may be any dielectric material used for creating substrate layers on conductive circuits for semiconductor and printed circuit board (PCB) processes. The insulative material 107 may have an adjustable thickness depending on the embodiment.

It should be understood that the conductive circuit 152 may be referred to herein as an “embedded circuit.” “Embedded,” as defined herein, means a process or product where a conductive circuit or layer is built in adjacent contact with a conductive layer, the conductive layer being etched away or otherwise removed to complete the conductive circuit of the substrate. Prior to etching, the thin foil sheet would short any circuit upon which the embedded substrate is built. In each of these “embedding” processes, the conductive layer is etched away to complete the functional conductive circuit.

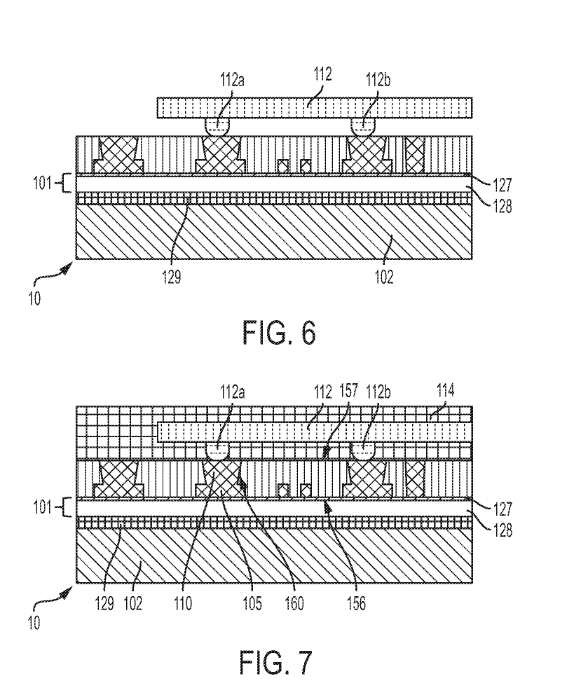

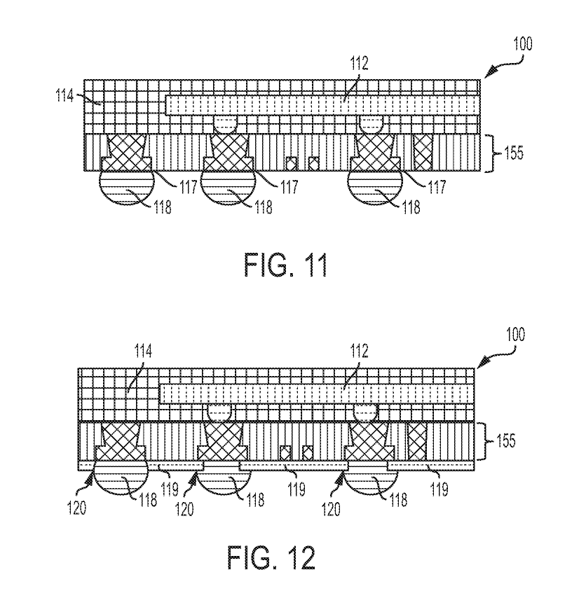

Referring now to FIG. 4, another step of the fabrication process is shown. At this stage, the insulative material 107 (e.g. PID) may be patterned. The patterning of the insulative material 107 may include one or more patterned structures 108 exposing a die attach pads 105 or patterned structures 109 exposing the thin conductive layer 127. As shown, multi-tier openings may be defined in the insulative material 107. The chip 112 (shown in FIG. 6) may also be placed on this stage with solder balls or copper pillars connecting to the circuits 152 within the patterned structures 108. Alternatively, the chip 112 may be placed as shown in FIG. 6.

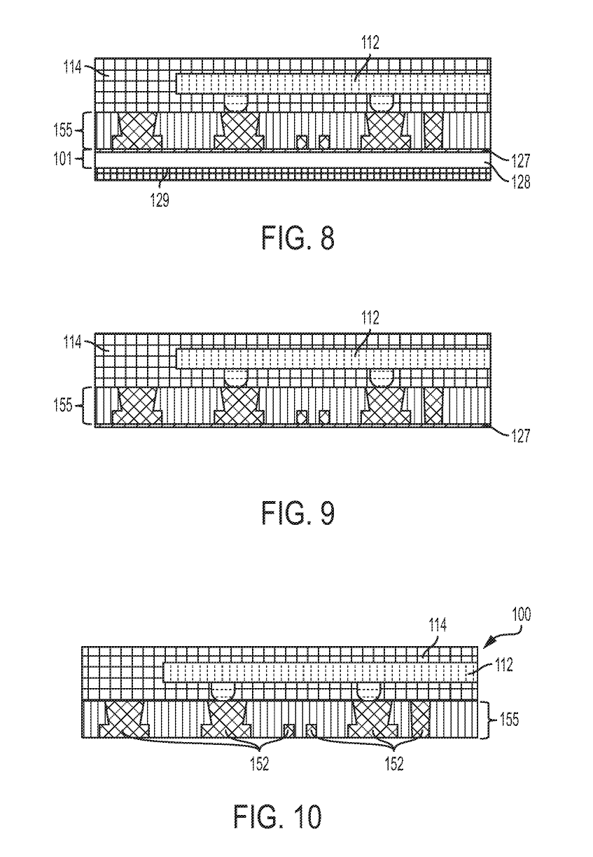

In FIG. 5, another step of the fabrication process is shown where the patterned structures 108, 109 may be filled with more conductive material, such as copper. In the embodiment shown, a plurality of copper plated filled vias 110 are shown filling the patterned structures 108. A copper plated structure 111 above the unpatterned thin foil 127 filled the patterned structure 109. The structures 110, 111 are each flush with the surface of the insulative material 107. At this point, the completed substrate layer 155 has been defined above the layer of thin foil 127. The substrate 155 includes a first surface 156 and a second surface 157. From here, it should be understood that multi-layer circuits may be fabricated above the substrate layer 155 by repeating the circuit patterning process using known build up or transfer methods. The embodiment described in FIGS. 1-12 includes the single substrate 155 but it should be understood that this is exemplary.

Once the substrate layer 155 is completed, before the next step, the electrical and/or mechanical properties of each die attach location may be tested or viewed with a vision system to determine good known die attach locations. This vision testing may be accomplished before the conductive circuit 152 is etched or completed and while the thin foil layer 127 remains attached. The insulative layer 107 may be comprised of PID material to facilitate the imaging at this stage prior to attachment of the semiconductor die 112. The imaging may determine whether the elements of the conductive circuit are ready for placement or are instead defective. It should be understood that the view shown in FIGS. 1-12 are for a single die attach location, but that the substrate may continue to the left and right (along with into and out of the page) relative to the cross section shown to provide for additional die attach locations.

Referring now to FIG. 6, a semiconductor die 112 may then be attached to the second surface 157 of the substrate layer 155. The semiconductor die 112 may be a flip chip or any other type of die and may include interconnects 112a, 112b. The interconnects 112a, 112b may be copper pillars or solder balls. The die placement and die redistribution of the semiconductor die 112 may be completed using pick and place tools. However, other die attach techniques may be required depending on the die pitch design and corresponding registration requirement. Flux application by dipping may also be incorporated during the pick and place. Other flux dispensing methods are possible in the placement process as well. Reflow may include utilizing a non conveyorized convection oven for large panel processes.

Thus, the conductive circuit 152 may include a first element 160 having a first portion such as the structure 110 in physical contact with the semiconductor die 112 and at least substantially coplanar with the second surface 157 of the insulative material and the substrate 155. The first element 160 may further include a second portion such as the structure 105 that is at least substantially co-planer with the first surface 156 of the substrate 155. The first structure 110 and the second structure 105 may have different geometries.

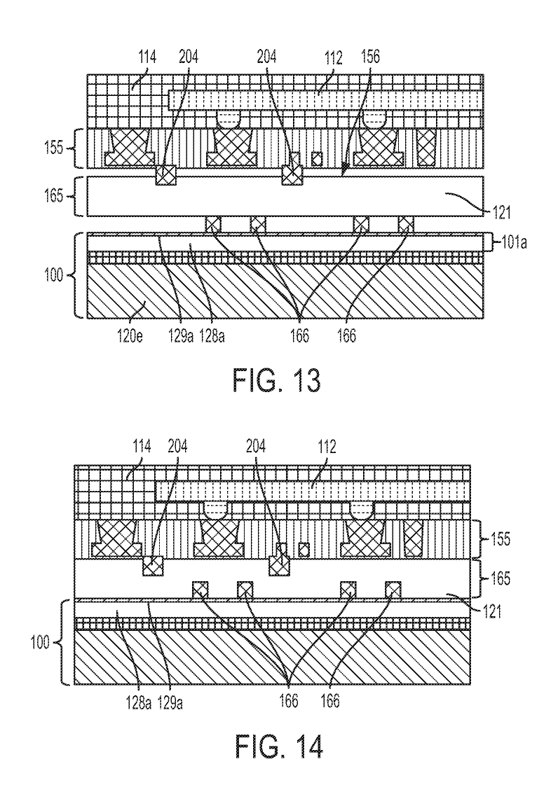

Referring now to FIG. 7, another step of the fabrication process is shown. The eighth step may include molding the die onto the substrate 155 and the carrier structure 10 with a mold compound 114. Mold sheets, powder or liquid molding compounds or systems may be used depending on the package requirements for the mold compound 114. Capilary underfill (CUF) is also an option rather than mold underfill (MUF). The mold compound 114 encapsulating the semiconductor die 112 may be a dielectric material instead of a mold material (e.g. ABF film), in other embodiments. Thus, the semiconductor die 112 may be attached to the substrate 155 and encapsulated with the mold 114 before the releasable carrier 120 is removed from the substrate 155 and the conductive layers 101.

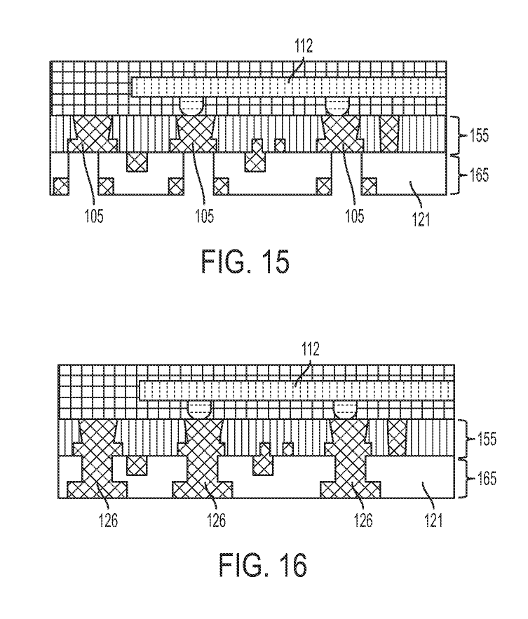

Referring to FIG. 8, the next step may include releasing the releasable carrier 120 from the conductive layers 101 and the substrate 155. The releasable carrier 120 may be removed by peeling. However, the release of the releasable carrier 120 may be facilitated by an activating source as described hereinabove. Thus, no mechanical peeling may be necessary if the level of adhesive is reduced to the point where the carrier 120 falls away from the conductive layers 101 and the substrate 155.

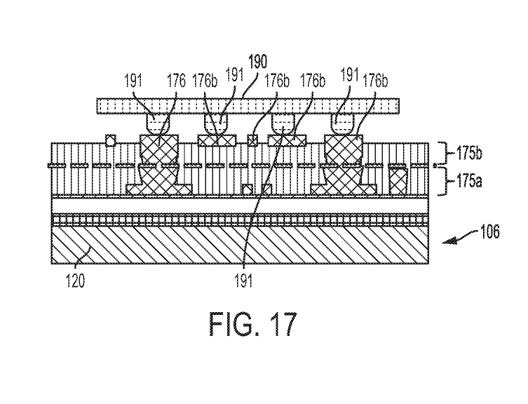

Referring now to FIG. 9, once the releasable carrier 120 is released from the conductive layers 101, the carrier foil 128 may be released from the thin foil 127. This may be accomplished by peeling. Because the carrier foil 128 may be thin relative to the releasable carrier 120 and may not require release facilitation with an activating source like the releasable carrier 120.

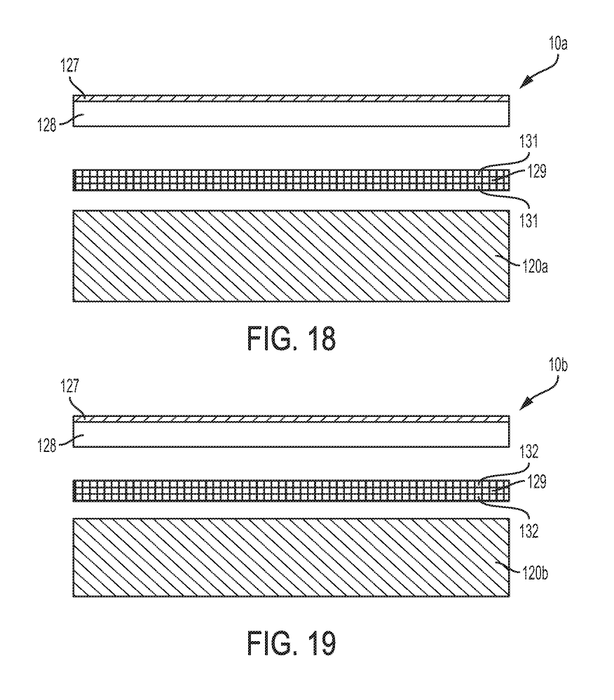

As shown in FIG. 10, once the assembled package is separated from the releasable carrier 120, the remaining thin foil 127 may be removed by etching to expose the embedded RLD circuits in the insulative material 107 in a tenth step in the fabrication process. This etching may form an etched layer 158 of the thin foil 127 conductive material. Thus, at this stage the conductive circuit 152 and the etched layer 158 form a completed circuit. The etching may be a control etching process that may completed to form or complete the embedded circuits in the substrate layer 155. Thus, the conductive circuit 152 may be formed as a result of the RDL circuit build up on the thin foil 127 which is then encapsulated by the insulative material such as a PID, an ABF film, prepreg, and mold compound. The embedded RDL circuits including die pads may then be completely formed and exposed after the releasable carrier 120 has been removed and the thin foil 127 that remains below the dielectric layer is etched away, as shown in FIG. 10.

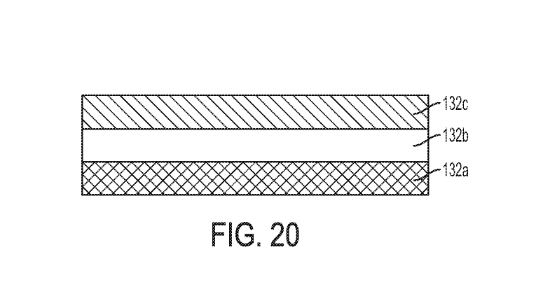

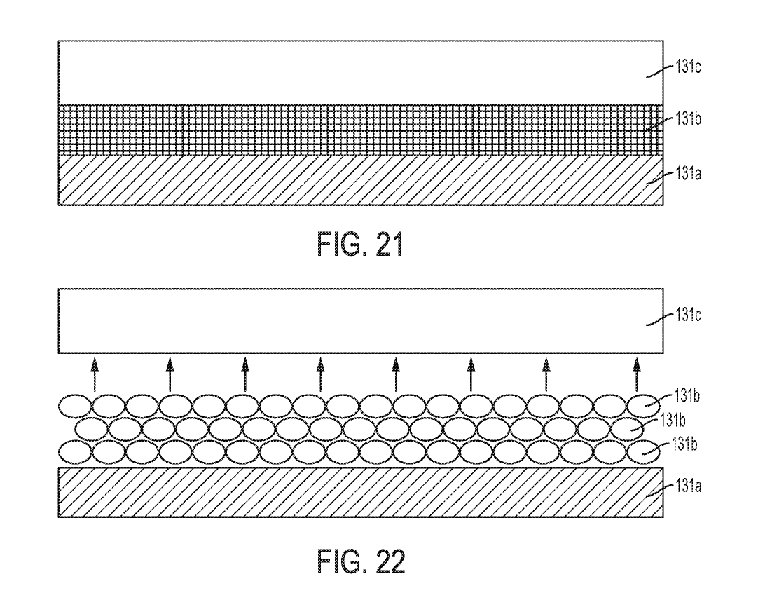

Referring now to FIGS. 11 and 12, the recessed embedded circuit 152 may form an opening for a ball grid array (BGA) ball attach process for completing the semiconductor device 100. In FIG. 11, the etched circuits may include solder ball attach locations 117 without solder masks for attachment to solder balls 118. In FIG. 12, the etched circuits may include solder mask defined (SMD) BGA ball attach. In particular, a solder mask material 119 may be applied in a manner creating a defined opening 120 for the solder balls 118.

Thus, the fabrication process described with respect to FIGS. 1-12 may be a hybrid assembly process, whereby the build-up and creation of the substrate 155 and the conductive circuit 152 are fabricated at the same time and location as the semiconductor die 112 is attached to the substrate 155. This process may create a completed semiconductor device 100 at the same time and in the same location. With the described hybrid assembly process, the substrate fabrication and the assembly process steps of attaching the semiconductor die 112 may be seamless and may occur on the same manufacturing line or by a single manufacturer. However, it should be understood that the carrier structure 10 may be utilized in other standard non-hybrid approaches as well.

It should be understood that the above steps described with respect to FIGS. 1-12 are an exemplary embodiment and that other fabrication processes which utilizes more, less or different steps are contemplated. For example, the carrier structure 10 may be utilized in the manner described in FIGS. 9-10 (e.g. using a thermal or UV adhesive) using a variety of different fabrication and packaging processes both before and after the release of the releasable carrier 120. Likewise, the concept of attaching the semiconductor die 112 prior to the underlying conductive circuit 152 being completed (i.e. before etching and/or before additional layers of substrate are applied) may be applicable in various other fabrication processes.

Further, the carrier structure 10 may be configured to allow for separation in a timely release sequence. The concept allows for separation at certain predetermined or preplanned stages in an assembly or fabrication process. In the embodiment above, the carrier structure 10 goes through RDL circuit patterning, dielectric build up, lamination and assembly (flip chip attach and molding). The phase where the releasable carrier 120 is separated from the package is after the molding process of the semiconductor die 112. The adhesive layer 129 or double sided tape is configured to maintain adhesion as the carrier goes through different processes, especially during heating steps such as reflow processes.

At this point in the process, the semiconductor die 112 is attached to the embedded substrate 155. The embedded substrate 155 has the first surface 156 and the second surface 157. The embedded substrate 155 includes the insulator layer 107 and at least a portion of a conductive circuit 152 within the insulator layer 107. The embedded substrate includes the etched layer 158 of the conductive etched thin foil 127. The etched layer 158 may be attached to the conductive circuit 152. The semiconductor die 112 is attached to the second surface 157 while the etched layer 158 of the conductive material is attached to the opposing first surface 156.

Thus, disclosed herein is a method for making a semiconductor device, such as the semiconductor device 100. The method may include patterning a conductive circuit, such as the conductive circuit 152 on a conductive layer, such as the thin foil 127. The method may include applying an insulator material, such as the insulative material 107, over the conductive circuit to create a substrate, such as the substrate 155, having a first surface and a second opposing surface, where the conductive layer is located on the first surface. The method may include attaching a semiconductor die, such as the semiconductor die 112, to the second surface of the substrate. The method may then include etching or removing the conductive layer to create a completed circuit. The method may include providing a releasable carrier, such as the releasable carrier 120, attached directly or indirectly to the conductive layer, encapsulating the semiconductor die after the attaching the semiconductor die, and removing the releasable carrier from the conductive layer after the encapsulating of the semiconductor die.

Another embodiment may include a method for making a semiconductor device, such as the semiconductor device 100. The method may include providing a releasable carrier, such as the releasable carrier 120, attached to a conductive layer, such as the thin foil 127. The method may include patterning a conductive circuit, such as the conductive circuit 152, on a surface of the conductive layer. The method may include applying an insulative material, such as the insulative material 107, at least partially covering the conductive circuit. The method may include releasing the releasable carrier from the conductive layer and facilitating the releasing with an activating source. This facilitating may occur without the activating source making physical contact with the releasable carrier. The method may include raising the temperature of an adhesive, such as the adhesive layer 129, located between the releasable carrier and the conductive layer, to a temperature between 150° C. and 300° C. The method may include attaching a semiconductor die, such as the semiconductor die 112, to at least portions of the conductive circuit. The method may include encapsulating the semiconductor die before the releasing the releasable carrier. The method may further include including activating the adhesive with the activating source to facilitate the releasing. The method may further include applying thermal release adhesive on one or both sides of a double sided tape of the adhesive. The method may alternatively or additionally include applying UV release on one or both sides of the double sided tape. Still further, the method may include removing the carrier foil layer from the thin foil layer after the releasable carrier has been released. Moreover, the method may include reusing the releasable carrier for making a second semiconductor device.

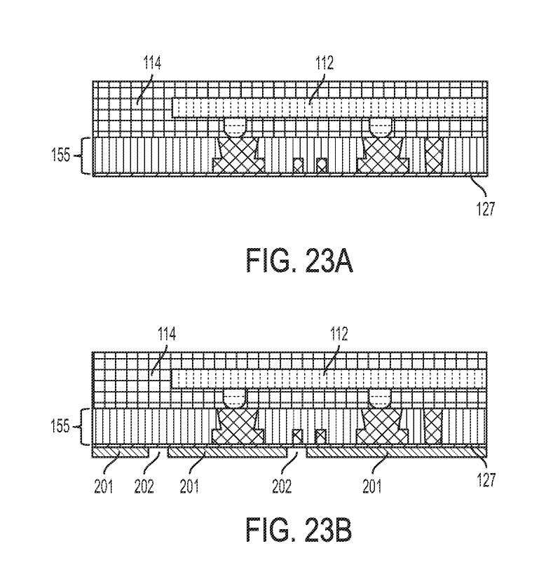

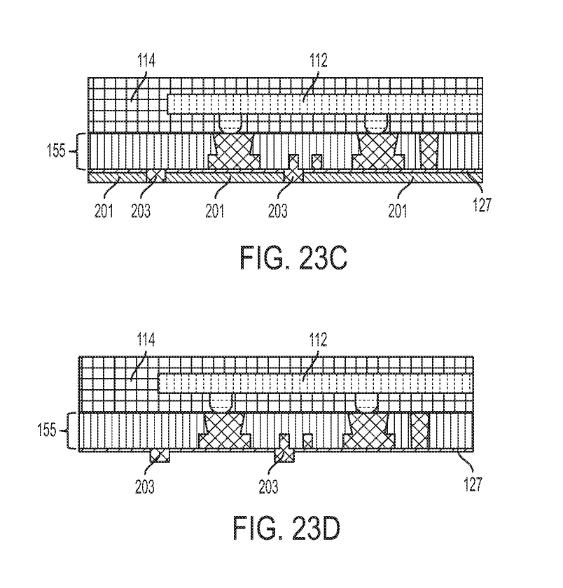

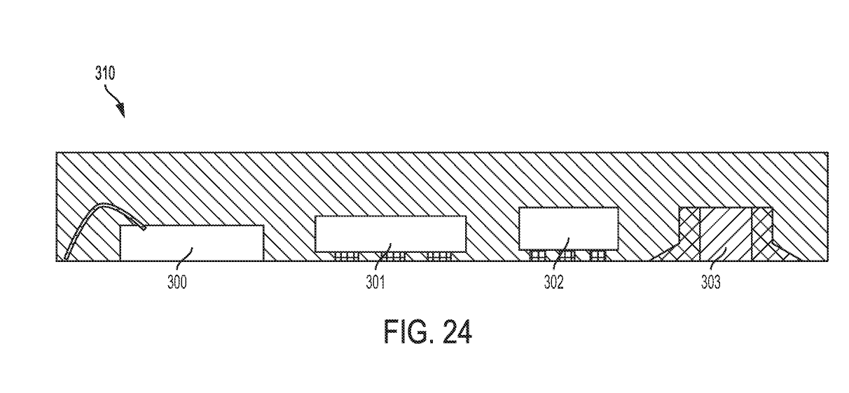

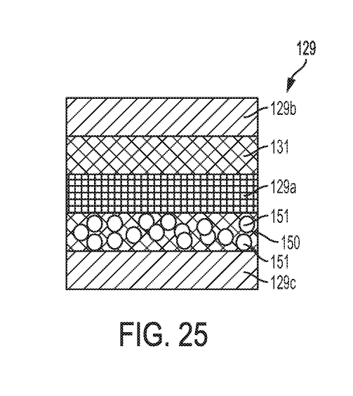

Referring now to FIGS. 13-16 it is contemplated that the fabrication process may forgo steps 11 and 12 until after applying one or more additional substrate layers such as the second substrate layer 165 shown in FIGS. 13-14. In this process multi-substrate process, the semiconductor die 112 may be attached directly to the circuit pads at the structures 110 without removing the releasable carrier 120. If additional RDL layers are necessary, they may be formed by transfer process or by a build-up process after the releasable carrier 120 is removed as shown in FIGS. 13-16. FIG. 13 shows another carrier structure 10e similar or the same as the carrier structure 10. Here, an above plane circuit 204 may have already been applied adjacent or above the first surface 156, along with another insulative layer 121 which may include, for example, a thermal cure dielectric. The carrier structure 10e may include an annular ring structure 166 patterned on the conductive layers 101a. The thermal cure dielectric may be compressed, as shown in FIG. 14. Referring to FIG. 15, the releasable carrier 120e of the carrier structure 10a has been removed, along with the carrier foil layer 128a, exposing the thin foil layer 129a, which has already been etched away. Laser ablate has been used to remove portions of the insulative material and to expose the top pads 105 in the first substrate 155. Vias 126 are filled with a conductive material in the step shown in FIG. 16. It should be understood that following the step shown in FIG. 16, additional layers may be similarly applied. Furthermore, build-up layers by transfer method without a releasable carrier may be applied as well.

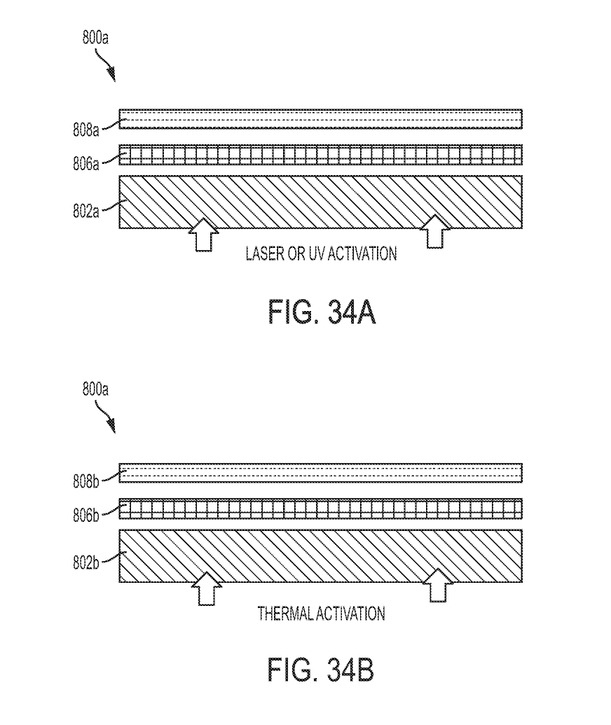

FIGS. 23a, 23b, 23c and 23d show a process for above plane structures applied above the etched layer. FIG. 23a shows a step after the semiconductor die 112 has been encapsulated in the mold 114, after the carrier tape 128 has been removed but prior to the etching. At the step shown in FIG. 23b, a photoresist pattern 201 has been applied adjacent to the thin foil layer 127 with a plurality of photoresist openings 202, prior to etching. Once this pattern has been established, FIG. 23c shows that above place circuits 203 may be plated on the thin foil layer 127. Once this occurs, etching the thin layer 127 may be accomplished to create the above plane circuits 204, as shown in FIG. 23d. Other processes for above plane conductive circuits are contemplated including standard build up layering. For example, once the etched layer with above plane circuits has been applied, another standard build up layer may be applied. Once the encapsulating mold 114 has been applied about the semiconductor die 112 and hardens, the die may act as the structural support upon which to build additional layers in a standard build process.

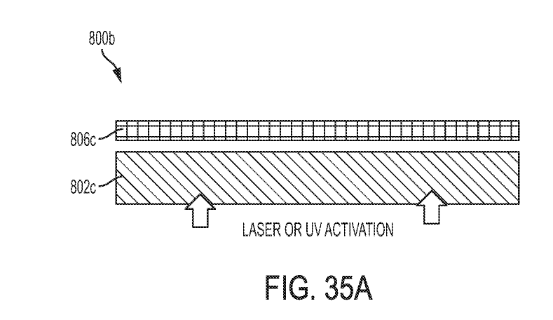

Referring to FIG. 24 package structure(s) with multiple active(s) and/or passive(s) combinations may be redistributed simultaneously. As shown, a wirebond 300, a flipchip 301, an IDP 302 and a passive component 303 are shown packaged together in a system in package (SIP) arrangement 310. This system in package approach as shown in FIG. 24 may be accomplished using the carrier structure 10 as described herein.

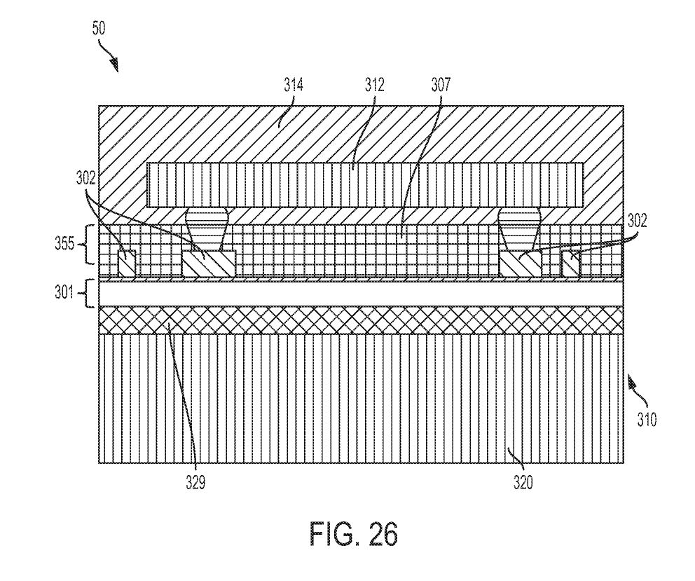

Referring now to FIG. 17, another embodiment is illustrated. In this embodiment, multiple RDL layers are formed on an underlying carrier structure 10b, the same or similar to the carrier structures 10, 10a. Here, embedded features may be located proximate to the BGA pads formed on the thin releasable foil of the carrier in a first substrate layer 175a. However, a second substrate layer 175b may be built upon the first substrate layer 175a using a standard build up process which results in at least some above plane conductive elements 176 which may be capture pads for receiving pillars or interconnects 191 of the semiconductor die 190. A dashed line is shown between layers 175a and 175b to highlight the difference in layers. However, it should be understood that this dashed line is imaginary and simply shown to demonstrate that there are two separate layers. Again, the attachment of the semiconductor die 190 may occur when the releasable carrier 120 remains attached before release in this embodiment.

FIG. 26 shows another embodiment of another semiconductor device 50 that is at least partially fabricated in a manner consistent with that described herein above. This semiconductor device 50 includes a conductive circuit 352 and a first layer of insulative material 307 which is a first mold material. A “mold” as described and used herein means a thermoplastic material having a substantial filler content. Additionally, a mold may mean a material having a substantial filler size as well. A mold material is further configured to protect the encapsulated conductive circuits 352. The first mold material 307 may encapsulate the conductive circuit 352 and may be configured to act as an electrical insulator and/or a dielectric. The conductive circuit 352 may be an embedded circuit that may eventually be completed by etching a thin foil layer, as described hereinabove. The first mold material and the encapsulated conductive circuit 352 may comprise a first substrate layer 355. The semiconductor device 50 may further include a semiconductor die 312 encapsulated within a second mold material 314. In other embodiments, the semiconductor die may be encapsulated within the first semiconductor material 307 that has been used to encapsulate the conductive circuit 352.

Consistent with the embodiments described hereinabove, semiconductor device 50 may be fabricated on a carrier structure 310 having a releasable carrier 320, an adhesive layer 329 and a releasable foil layer 301. The substrate 355 may be built upon the releasable carrier, which may include the adhesive layer 329 which may be thermally or UV activated. As shown, the semiconductor die 312 may be encapsulated with the second mold material 314 before the releasable carrier 320 has been removed or released from the substrate 355 and the package structure.

The first mold material 307 and the second mold material 314 may be a thermoplastic mold compound which is able to soften upon heating, and is capable of being hardened upon cooling. This softening and hardening may be repeatable for additional heat applications without compromising the integrity of the eventually hardened compound. This may be particularly advantageous for embodiments in the present invention, which may require additional heat applications for removing the releasable carrier 320, in the case that the adhesive layer 329 is a thermally releasable compound. The first mold material 307 may not be mixed with thermosetting dielectric materials. The first mold compound 307 may function in a similar manner to thermosetting dielectric materials such as ABF film and PID and other dielectric materials, but the first mold compound 307 may actually be a thermoplastic compound. The first mold material 307 layer may also be thinner than the second mold material 314 layer, as the first mold material 307 is configured to function as a prepreg or dielectric encapsulate material.

In one embodiment, the second mold material 314 may be different than the first mold material 307. It may be particularly advantageous in some fabrication processes for the first mold material 307 to have a lesser filler content than the second mold material 314. Similarly, the first mold material 307 may have a filler size that is less than the second mold material 314. By having a greater filler content and filler size than the first mold material 307, the second mold 314 material may prevent warpage and may be particularly advantageous. Having a lower filler content and filler size for the first mold material 307 may be desirable for achieving precise and thin fill dimensions necessary for creating substrate layers.

Overall, this double mold process may allow for packages with redistribution layers to be processed by the sole use of thermoplastic molding compounds and without the use of thermosetting dielectric materials, in one embodiment. There are benefits of using thermosetting mold compounds for the entire package structure resulting in less mismatch in material properties such as CTE, Tg, and resin rheology. This may allow the material and process adjustment to control warpage and other reliability concerns. The double mold process may be incorporated into current assembly line infrastructures already designed to handle mold compound materials. In the case of a multi-layer package design, the package construction may require a combination of thermosetting and thermoplastic materials. It should further be understood that dielectric substrate layers may be applied below the first substrate layer 355 once the carrier assembly 310 has been removed and the thin foil has been etched in the manner described hereinabove. Thus, the single substrate layer 355 adjacent to the semiconductor die 312 may be made with mold in the manner described herein, but additional layers may be built up in a standard build-up process using dielectric materials.

Another embodiment contemplated is a method of making a semiconductor device that includes providing a substrate, such as the substrate 355, that includes a first mold material, such as the first mold material 307, and a conductive circuit, such as the conductive circuit 352, in the first mold material. The method may include providing a semiconductor die, such as the semiconductor die 312. The method may include attaching the semiconductor die to the conductive circuit and encapsulating the semiconductor die with at least one of the first mold material or a second mold material, such as the second mold material 314. The method may include preventing the mixing of the first mold material with thermosetting dielectric materials. The method may include encapsulating the semiconductor die with the second mold material. The method may include created an embedded the conductive circuit by etching a conductive layer or sheet. The method may further include insulating an entire package structure of a semiconductor device by the sole use of one or more mold compounds. The method may further include providing a thermally activated releasable carrier, such as the releasable carrier 320, building a substrate, such as the substrate 355, upon the thermally activated releasable carrier, attaching the conductive circuit before the thermally activated releasable carrier is removed from the substrate. The method may include exposing the thermally activated releasable carrier to an appropriate temperature, and releasing the thermally activated releasable carrier.

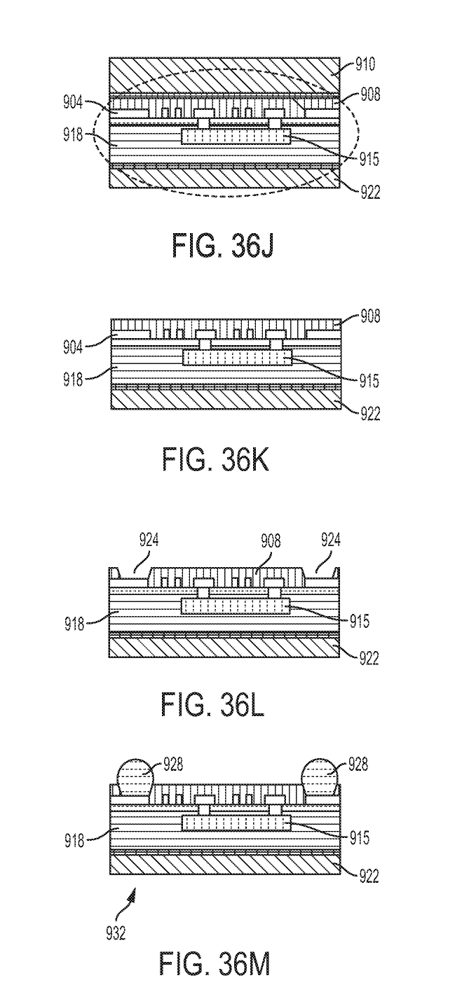

FIGS. 27 shows still another embodiment of a semiconductor device 400 having an interconnection joint structure 401. Shown is a semiconductor device 400 having a semiconductor die 412 at a stage in a fabrication process prior to encapsulation of the semiconductor die 412 with a mold. The package shown may be resting on a carrier structure (not shown) in a manner consistent with the embodiments of the carrier structures described herein above. Thus, a thin foil layer (not shown) may rest below a substrate 455 shown. The substrate 455 may include a conductive circuit 452 and an insulative material 407. The substrate 455 may further include a first surface 456 that is adjacent to the conductive layer or other base and a second surface 457 that is proximate or facing the semiconductor die 412. The semiconductor die 412 is shown attached to the substrate above or proximate the second adjacent to the second surface 457.

The semiconductor device 400 may include the interconnect joint structure 401 in the substrate 455 creating a capture pad 405. The interconnect joint structure 401 may include a copper layer 410 and an adjacent top nickel layer 411 and an adjacent bottom nickel layer 412. Thus, the interconnect joint structure 401 may define a capture pad 405 which includes the first nickel layer 411 followed by the copper layer 410 and the second nickel layer 412. This interconnect joint structure 401 may be found in a single layer of the insulative material 407 or a single applied layer of the substrate 455. The semiconductor die 412 may be attached to the substrate 455 in this manner without a via. In one embodiment, the substrate 455 and the interconnect joint structure 401 may be formed using a build-up process. In another embodiment, a subtractive process may be utilized (i.e. with laser ablation of the insulative material, for example). While the layers 411, 412 have been described as nickel, other embodiments are contemplated where the layers 411, 412 are made of other metals, such as zink or other plating metals.

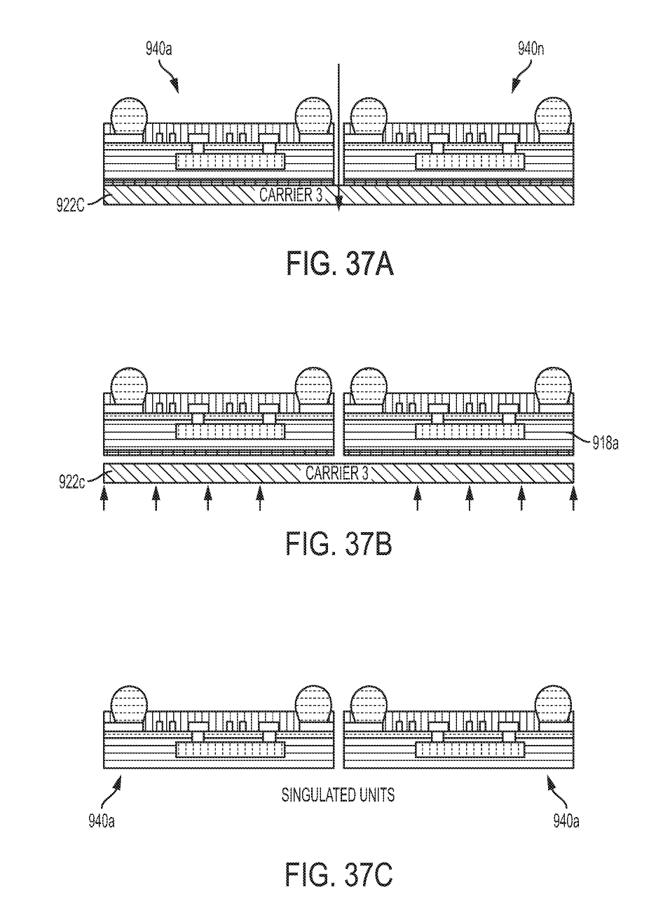

The nickel layers 411, 412 may be plated layers that are particularly configured to protect during solder or pillar attachment of the semiconductor die 412 when very thin insulative encapsulation layers are necessary. For example, if the insulative layer 407 is very thin (i.e. below 12 μm thick), the insulative layer 407 (e.g. dielectric, PID or ABF film) may act as a soldermask defined (SMD) for the pad opening. The nickel layers 411, 412 may provide a barrier to prevent copper consumption by solder (Sn-Pb) during joint intermetallic formation using pillars 420 and solder balls (as shown in FIG. 28).

An additional nickel layer 415 may be provided adjacent to the first surface 456. This nickel layer 415 may function as an etch stop barrier during thin foil etching from a carrier structure as described hereinabove. A copper layer 416 may be provided above the nickel layer 415. The nickel layer 415 may control the integrity of fine line circuits (e.g. 2 μm) of the conductive circuit 452 from over etching and poor etching tolerances. Other suitable plating materials are also contemplated other than nickel to provide a barrier, such as zinc.

Referring now to FIG. 28, an embodiment is shown similar to the embodiment shown in FIG. 27. Here, a semiconductor device 500 is shown having a semiconductor die 512 with solder balls 514. This embodiment shows an interconnect joint structure 501 that may be applicable to instances when the semiconductor die 512 includes the solder balls 514 instead of the copper pillar 420, and where the insulator acts as a soldermask defined. In this embodiment, a single layering process including a first nickel layer 516 followed by a copper layer 518 and another nickel layer 520 are shown to create the interconnect 501. Further, the first nickel layer 516 may be applied to all of the conductive elements to act as an etch barrier, as shown.

Another embodiment includes a method for making a semiconductor device that includes providing a substrate, such as the substrate 455, and an insulative layer, such as the insulative layer 107 over the conductive circuit. The method may include forming a capture pad, such as the capture pad 405, in the substrate including a first layer of nickel, such as the first nickel layer 411, a layer of copper over the first nickel layer, such as the layer of copper 412, and a second layer of nickel over the layer of copper, such as the second layer of nickel 411. The method may include etching a layer of copper foil, such as the thin foil on a surface of the substrate. The method may include including the first layer of nickel, the layer of copper, and the second layer of nickel within a single layer of the insulator. The method may include providing a semiconductor die, such as the semiconductor die 512, and attaching the semiconductor die to at least a portion of the conductive circuit without a via. The method may include providing a nickel layer, such as the nickel layer 415, in the substrate to act as an etch stop barrier between the etched foil layer and the conductive circuit. The method may include the semiconductor die including solder balls, such as the solder balls 514, and attaching the solder balls to at least one of the first and second layers of nickel.

Referring back to FIGS. 27 and 28, another embodiment is contemplated whereby the layers 416, 418 and 516, 518 may have a bi-metal structure. In one case, the bi-metal structure may be a copper and nickel structure. In one embodiment, the metals may be joined together through heat. The metals may each have different coefficients of thermal expansion in one embodiment. Further, the layers 416, 418 and 516, 518 may allow for the plating of ultra-fine nickel barriers (i.e. less than or equal to 3 μm) plated onto the copper foil. These ultra-fine levels may create patterned circuit lines that are less than 3 μm, for example 2 μm, or as little as 1 μm or less. The nickel structure 416, 516 may provide for this ultra-thin plating.

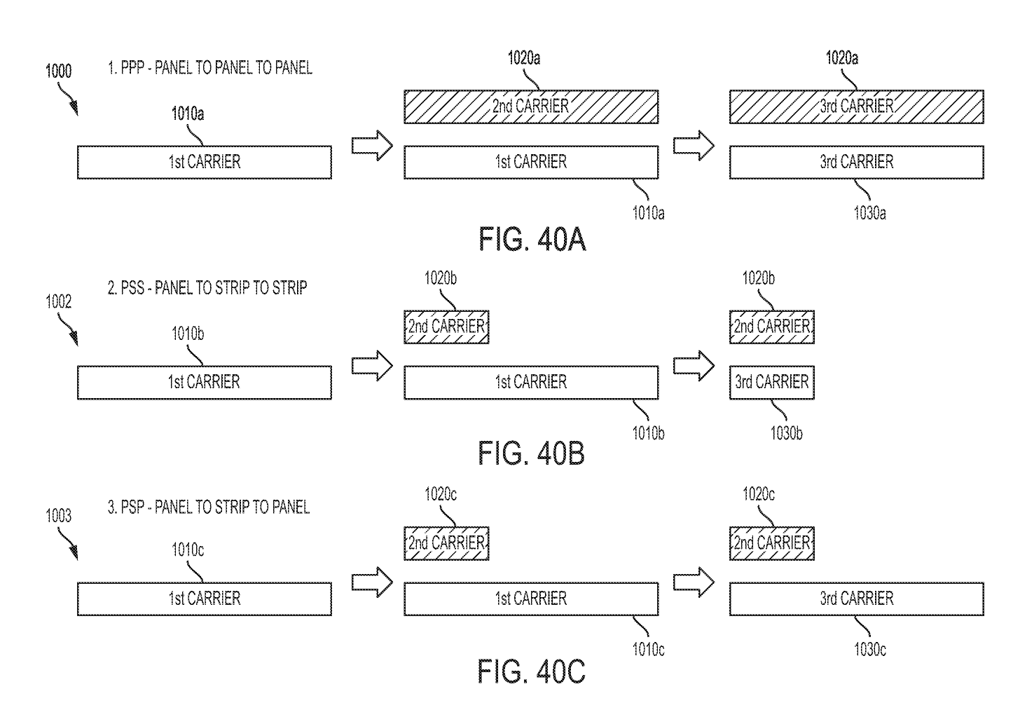

FIG. 31 depicts an embodiment of a multiple step release process for creating a releasable carrier structure 600 in accordance with one embodiment. In this embodiment, a carrier layer 610 is shown. The carrier layer 610 may be a glass carrier, in one embodiment. Other examples are contemplated, as described above. A releasable tape layer 612 is shown attached to the carrier layer 610 in a layer above the carrier layer 610. In one embodiment, the releasable tape layer 612 may be REVALPHA tape or the like. A copper layer 614 is shown attached to the releasable tape layer 612 in a layer above the releasable tape layer 612. An aluminum layer 616 is shown attached to the copper layer 614 in a layer above the copper layer 614. Thus, a four layer structure is shown having the layers 610, 612, 614, 616. In this embodiment, two release points are contemplated: a first release point 618 between the glass layer 610 and the releasable tape layer 612, and a second release point 620 between the releasable tape layer 612 and the copper layer 614.

In this embodiment, the copper layer 614 and the aluminum layer 616 may be a copper layer bonded on an aluminum carrier held by an adhesive, such as an organic adhesive. In another embodiment, the copper layer 614 may be welded along the edges through ultrasonic welding to the aluminum layer 616. In both the cases of bonding with an adhesive and welding around the edges, the aluminum layer 616 may be released from the copper layer 614, as shown, by cutting the material inside the adhesive or welded area. Inside this adhesive or welded area, the copper layer 614 may not be adhered or welded to the aluminum layer 616.

Thus, in this embodiment, the copper layer 614 is attached to the to the releasable tape layer 612, which may be also adhered or attached to the carrier layer 610. The edges of the aluminum layer 616 may remain adhered or welded to the copper layer 614 but the remainder of the aluminum layer 616 may not be adhered or attached to the copper layer 614. Once the edges are cut away, the aluminum layer 616 separates freely from the copper layer 614, as shown in the second step. In the third step, the copper layer 614 may be etched to create a circuit. From there, later steps (not shown) may include building up layer(s) on the copper layer 614 and bonding a chip to the built copper layer(s) 614. Once the chip construction is complete, activation may occur to release the carrier layer 610 and the releasable tape layer 612 at the release points 620, 618, respectively. In this manner, only two activated release points 620, 618 are contemplated.

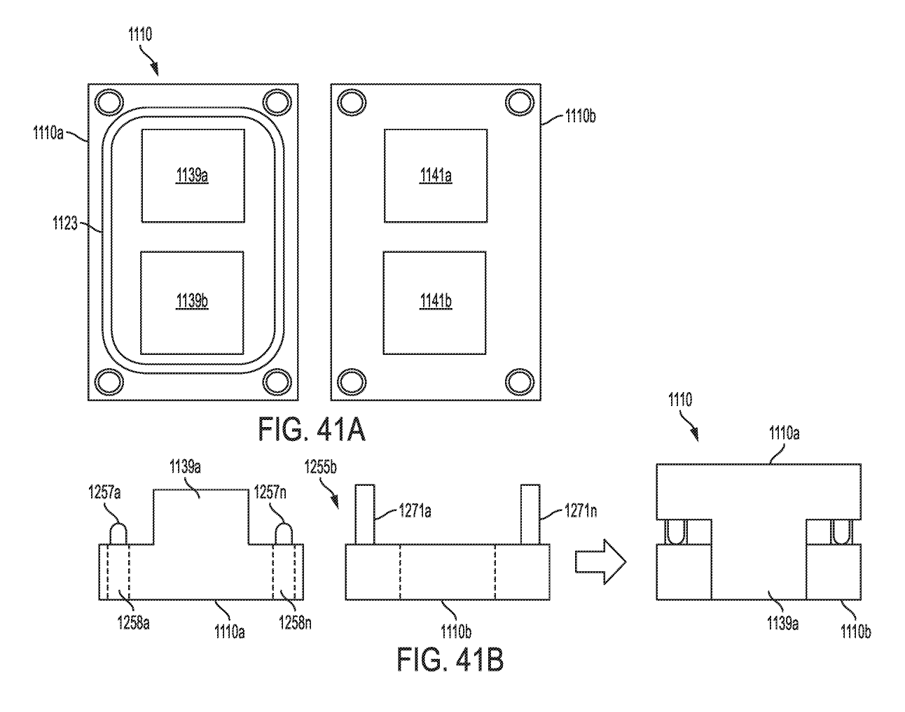

FIG. 32 depicts another embodiment of a multiple step process for creating a releasable carrier structure 700 in accordance with one embodiment. In this embodiment, a carrier layer 710 is shown. The carrier layer 710 may be a glass carrier, in one embodiment. Other examples are contemplated, as described above. A releasable tape layer 712 is shown attached to the carrier layer 710 in a layer above the carrier layer 710. In one embodiment, the releasable tape layer 712 may be REVALPHA tape or the like. In this embodiment, an aluminum layer 716 is shown attached to the releasable tape layer 712 in a layer above the releasable tape layer 712. A copper layer 714 is shown attached to the aluminum layer 716 in a layer above the aluminum layer 716. Thus, a four layer structure is shown having the layers 710, 712, 716, 714. In this embodiment, two release points are contemplated: a first release point 718 between the glass layer 710 and the releasable tape layer 712, and a second release point 720 between the releasable tape layer 712 and the aluminum layer 716.

In this embodiment, the aluminum layer 716 is attached to the to the releasable tape layer 712, which may be also adhered or attached to the carrier layer 710. In a second step, the copper layer 714 may be etched to create a circuit. From there, later steps (not shown) may include building up layer(s) on the copper layer 714 and bonding a chip to the built copper layer(s) 714. Once the chip construction is complete, activation may occur to release the carrier layer 710 and the releasable tape layer 712 at the release points 720, 718, respectively. In this manner, only two activated release points 720, 718 are contemplated. Once the chip construction is complete and the carrier layer 710 and releasable tape layer 712 are removed, the aluminum layer 716 may be exposed. From here, the aluminum layer 716 may be removed by preferential etching whereby the aluminum layer 716 is removed without effecting the copper layer 714. This removal of the aluminum layer 716 may require one, two, or more chemicals.

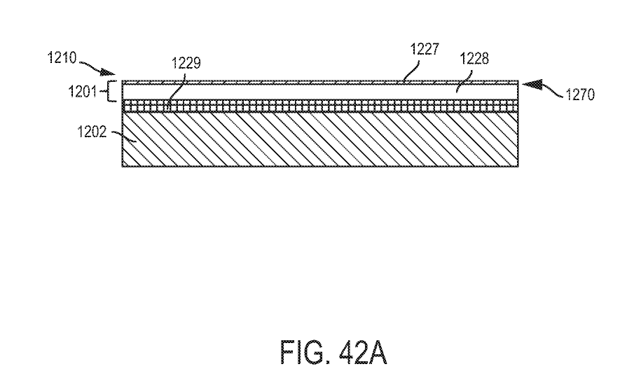

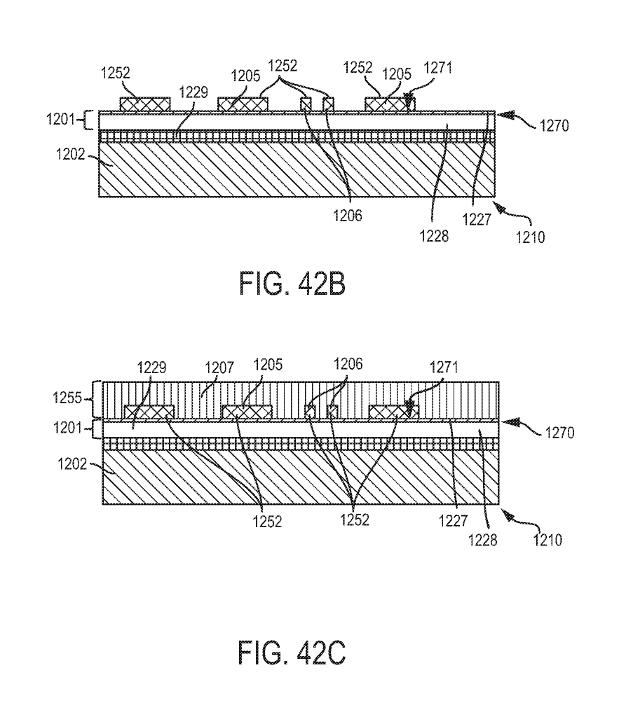

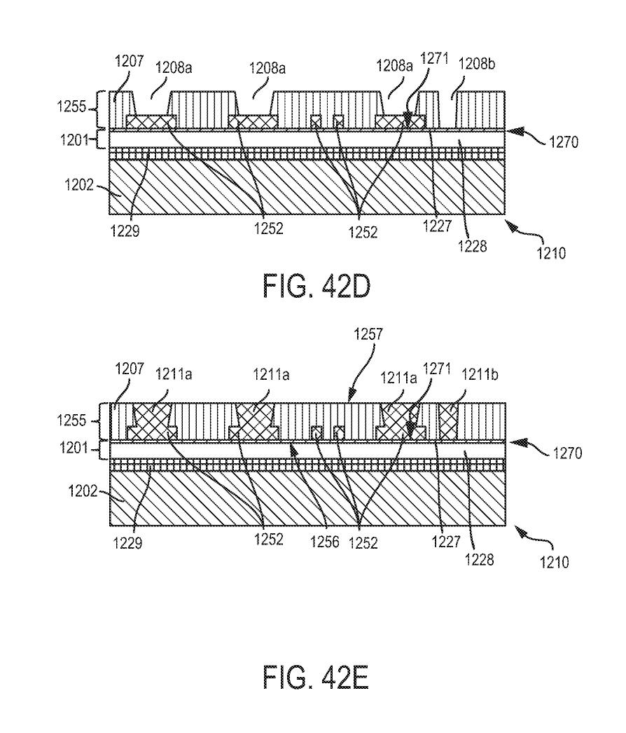

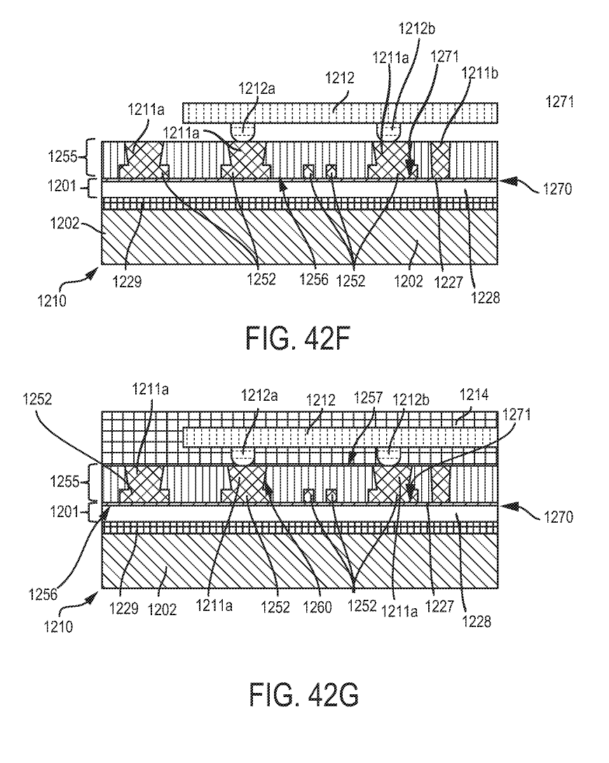

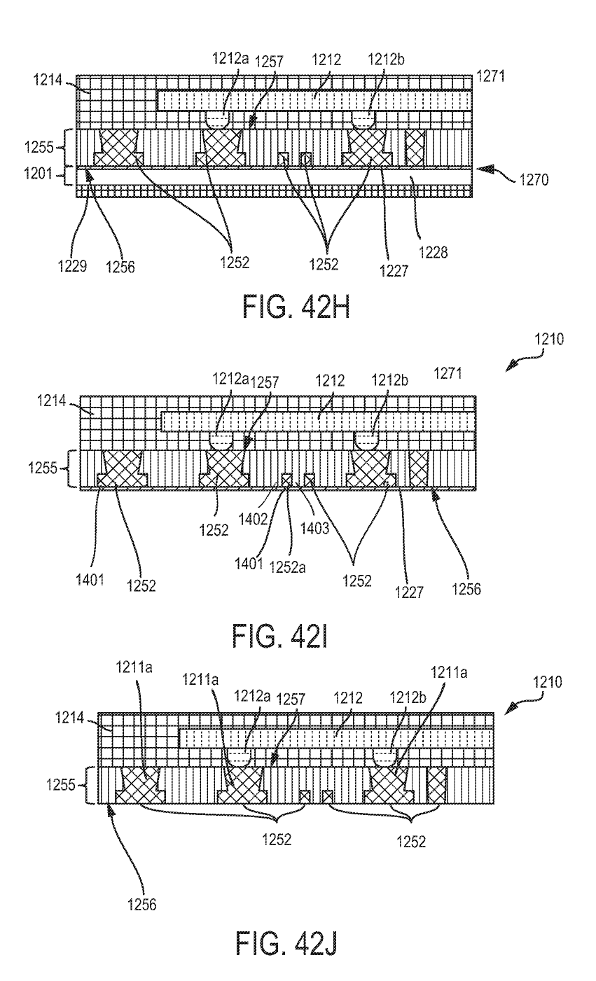

Referring now to FIG. 33, an alternative embodiment of a carrier structure 800 is illustrated whereby multiple semiconductor carriers (i.e., carrier 802 and carrier 804) are used, in accordance with embodiments of the present invention. Carrier structure 800 includes a first portion 800a including a carrier 802 and a releasable tape or adhesive layer 806a attached to a dielectric layer 808 (e.g., a mold sheet layer, ABF spin on films layer, etc.) formed as an encapsulation layer surrounding formed circuit structures 812a . . . 812n formed from a releasable copper foil layer 810. Additionally, carrier structure 800 includes a second portion 800b including a carrier 804, a releasable tape layer 806b, and a releasable copper foil layer 810. Carrier 804 comprises a base carrier for providing a backing structure for use during a redistribution layer (RDL) process. Carrier 802 is removed from carrier structure 800 before carrier 804 is attached to carrier structure 800. Carrier 804 may be removed from carrier structure 800 via a laser/UV release process, a thermal release process, etc after a redistribution layer (RDL) and a circuit layer has been completed. Carrier 802 provides a backing structure for use during an assembly process. Additionally, carrier 802 provides a backing structure for enabling an electrical testing procedure. Carrier 804 may include, among other things, a glass carrier. Carrier 804 may be removed from carrier structure 800 after an additional carrier (e.g., carrier 802c as described with respect to FIG. 35b, infra) is attached to carrier structure 800 as described with respect to FIGS. 35b and 36a-36m, infra. Carrier 804 may be removed from carrier structure 800 via a laser/UV release process, a thermal release process, etc. Carrier structure 802 and carrier structure 804 may be removed or separated from carrier structure 800 via laser activation, UV activation, and/or thermal activation. A third carrier structure (e.g., carrier structure 922 as illustrated in FIG. 36J, infra) may be released via a UV or laser activation process due to usage of a glass carrier material. Carrier structure 804 comprises a panel format (P). Carrier structure 802 may comprise a strip format (S) or a panel format (P). A third carrier structure may comprise a strip format (S) or a panel format (P). Therefore, the entire semiconductor structure comprising all three carrier structures (carrier structure 802, carrier structure 804, and the third carrier structure) may respectively be formed as: (1) PPP (panel to panel to panel), (2) PSS (panel to strip to strip), or (3) PSP (panel to strip to panel). With respect to embodiments associated with the PSS option and the PSP option, an RDL circuit associated with a panel format on a first carrier structure must be singulated via a laser process into strip size in order to match a carrier structure (i.e., carrier structure and a releasable adhesive) in strip format. An alternative embodiment that includes an all panel format (PPP) is associated with an RDL circuit on a panel that does not require execution of a laser singulation process (i.e., an all panel processing format). The aforementioned embodiments apply to FIGS. 36a-36m as described, infra. A laser ablation/singulation technique as illustrated with respect to FIG. 37, infra may be used for singulation with respect to the carrier structure from panel to strip format (i.e., after FIG. 36c), instead of a panel to unit singulation process. The additional carrier enables a laser singulation process to be performed to convert a panel size to a unit size with respect to the additional carrier. Releasable tape layer 806a and 806b may each alternatively include an adhesive layer. Additionally, the first carrier structure (as illustrated in FIGS. 34A and 34B) includes a copper layer, a releasable adhesive layer, and a backing carrier structure (i.e., glass or stainless steel). The second and third carrier structures include releasable adhesive and a backing carrier structure as illustrated in FIG. 35.

FIG. 34a illustrates a first alternative embodiment for the first portion 800a of the carrier structure 800 of FIG. 33, in accordance with embodiments of the present invention. The first portion 800a (illustrated in FIG. 34a) includes a glass carrier 802a attached to a conductive copper releasable (or non-releasable) foil layer 808a via a releasable (via thermal, UV, or laser releasable activation) adhesive layer 806a. Glass carrier 802a comprises a panel format used for circuit build up purposes as illustrated with respect to FIGS. 18 and 19, supra.

FIG. 34b illustrates a second alternative embodiment for the first portion 800a of the carrier structure 800 of FIG. 33, in accordance with embodiments of the present invention. The first portion 800a (illustrated in FIG. 34a) includes a metal core carrier 802b attached to a conductive copper releasable foil layer 808b via a releasable (via thermal activation) adhesive layer 806b.

FIG. 35a illustrates an alternative embodiment for the second portion 800b of the carrier structure 800 of FIG. 33, in accordance with embodiments of the present invention. The second portion 800b (illustrated in FIG. 35a) includes a glass carrier 802c attached to a releasable (via UV activation) adhesive layer 806c. carrier test

FIG. 35b illustrates an alternative embodiment for the additional carrier 800c of the carrier structure 800 of FIG. 33, in accordance with embodiments of the present invention. The additional carrier 800c (illustrated in FIG. 35b) includes a glass carrier 802d attached to a releasable (via UV activation) adhesive layer 806d.

FIGS. 36a-36m illustrate a fabrication process for the creation or fabrication of carrier structure 800 of FIG. 33, in accordance with embodiments of the present invention.

FIG. 36a illustrates a step of providing a releasable chip carrier 900 that is attached to a conductive layer(s) 902 to create a carrier structure.

FIG. 36b illustrates a step of forming a circuit layer 904 on a surface of the conductive layer(s) 902 to create a carrier structure.

FIG. 36c illustrates a step of forming a dielectric layer 908 on a surface of the circuit layer 904 to create a carrier structure.

FIG. 36d illustrates a step of attaching a releasable chip carrier 910 to a surface of the dielectric layer 908 to create a carrier structure as illustrated with respect to FIG. 33. Releasable chip carrier 900 and releasable chip carrier 910 may each include a panel size format, a strip size format, etc.

FIG. 36e illustrates a step of releasing releasable chip carrier 900 from the conductive layer 902 via facilitation of an activating source. The activating source may include any type of activating source including, inter alia, a UV light activating source, a thermal activating source, any type of laser releasing activating source, etc.

FIG. 36f illustrates a step of etching the conductive layer(s) 902 for removing at least a portion of the conductive layer(s) 902 from the circuit layer 904.

FIG. 36g illustrates a step of operationally testing circuitry of the circuit layer 904. Operationally testing the circuitry may include testing the circuitry for any malfunctions, etc.

FIG. 36h illustrates a step for attaching a semiconductor die 915 to portions of the circuit layer 904.

FIG. 36i illustrates a step for forming an encapsulating layer 918 surround the semiconductor die 915.

FIG. 36j illustrates a step of attaching a releasable chip carrier 922 to a surface of the encapsulating layer.

FIG. 36k illustrates a step of releasing releasable chip carrier 910 from the surface of the dielectric layer 908 via facilitation of an activating source. The activating source may include any type of activating including, inter alia, a UV light activating source, a thermal activating source, etc.

FIG. 36l illustrates a step of removing portions of the dielectric layer 908 thereby forming openings 924 within the dielectric layer. Alternatively

FIG. 36m illustrates a step of forming ball grid array structures within the openings 924. The ball grid array structures 928 are electrically connected to the semiconductor die 915. FIG. 36m illustrates a complete semiconductor package 932.

FIGS. 37a-37c illustrate a laser singulation process for generating multiple semiconductor packages 940a . . . 940n, in accordance with embodiments of the present invention. Each of the semiconductor packages 940a . . . 940n generated in combination (on large releasable chip carriers for forming

multiple semiconductor packages) as described with respect to the steps illustrated in FIGS. 36a-36m

FIG. 37a illustrates the step (performed after step described with respect to FIG. 36M) of applying a laser cut through all semiconductor package layers between semiconductor package 940a and 940n and through releasable chip carrier 922. Alternatively, the laser cut process may be performed after the step described with respect to FIG. 36C due to conversion from panel format to strip format with respect to carrier 900.

FIG. 37b illustrates the step of releasing releasable chip carrier 922 from a surface of an encapsulating layer 918a thereby forming the singulated semiconductor packages 940a . . . 940n of FIG. 37c.

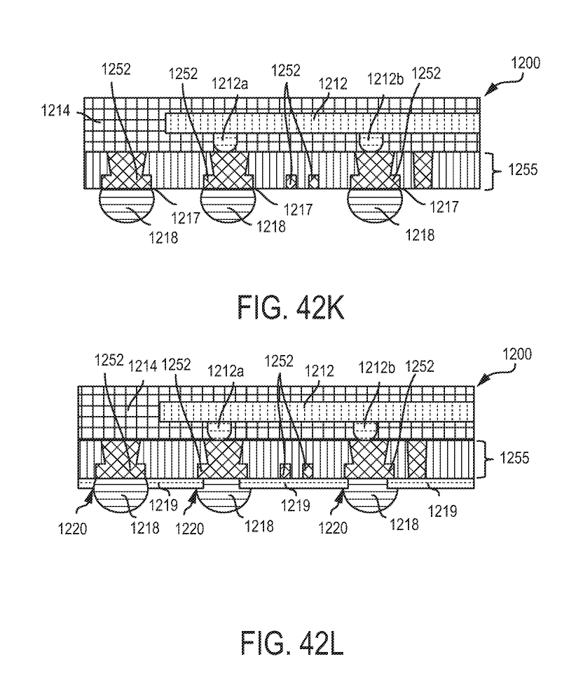

FIG. 38 illustrates the operational test step of FIG. 36g, in accordance with embodiments of the present invention. FIG. 38 illustrates a semiconductor package structure 952 comprising a plurality of semiconductor packages 952a . . . 952n on a single releasable chip carrier 955 prior to performing a laser singulation process for dividing each of semiconductor packages 952a . . . 952n from each other. Semiconductor package structure 952 is enabled for performing a redistribution layer (RDL) test and an automated optical inspection (AOI) process with respect to each of semiconductor packages 952a . . . 952n. The operational testing process may be executed as follows: a single layer is patterned on a first RDL layer and in response, a complete RDL test is executed prior to attaching a semiconductor die to the structure. Additionally, test pads 959a . . . 959n are generated and connected to each BGA 957a . . . 957n and a laser ablation process is performed for exposing the test pads 959a . . . 959n. Upon completion of the testing process, a singulation process is executed for removing all test lines 961a . . . 961n and test pads 959a . . . 959n.

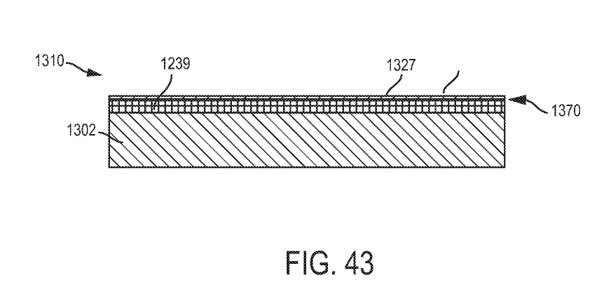

FIG. 39 illustrates an alternative test step with respect to the process of FIG. 38, in accordance with embodiments of the present invention. FIG. 39 illustrates a semiconductor package structure 975 comprising test pads 977a . . . 977n connected to BGA pads 977a . . . 977n via traces 980a . . . 980n. A laser ablation process is executed for exposing test pads 977a . . . 977n. Test pads 977a . . . 977n are configured to connect BGA pads 977a . . . 977n to signal circuits for executing a complete closed loop test associated with all electrical circuitry. Test pads 977a . . . 977n and traces 980a . . . 980n are removed after all semiconductor packages are singulated into independent semiconductor packages.

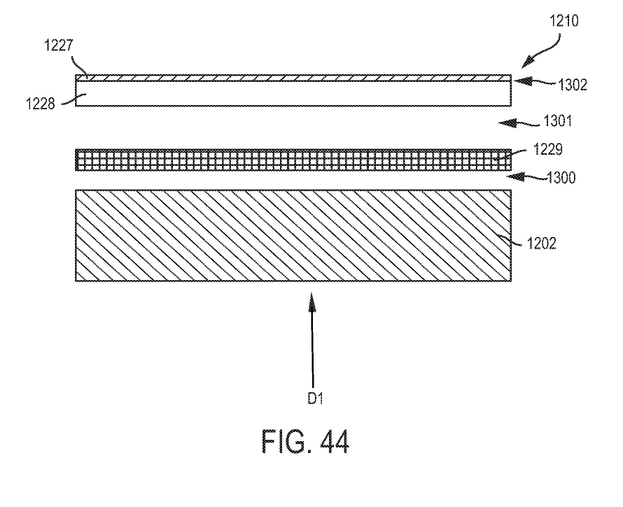

FIG. 40a illustrates a first flow diagram 1000 associated with a carrier structure panel to panel to panel (PPP) format, in accordance with embodiments of the present invention. The first flow diagram 1000 includes a first carrier structure 1010a in panel format, a second carrier structure 1020a in panel format, and a third carrier structure 1030a in panel format.

FIG. 40B illustrates a second flow diagram 1002 associated with a carrier structure panel to strip to strip (PSS) format, in accordance with embodiments of the present invention. The first flow diagram 1002 includes a first carrier structure 1010b in panel format, a second carrier structure 1020b in strip format, and a third carrier structure 1030b in strip format.

FIG. 40C illustrates a third flow diagram 1003 associated with a carrier structure panel to strip to panel (PSP) format, in accordance with embodiments of the present invention. The third flow diagram 1003 includes a first carrier structure 1010c in panel format, a second carrier structure 1020c in strip format, and a third carrier structure 1030c in panel format.

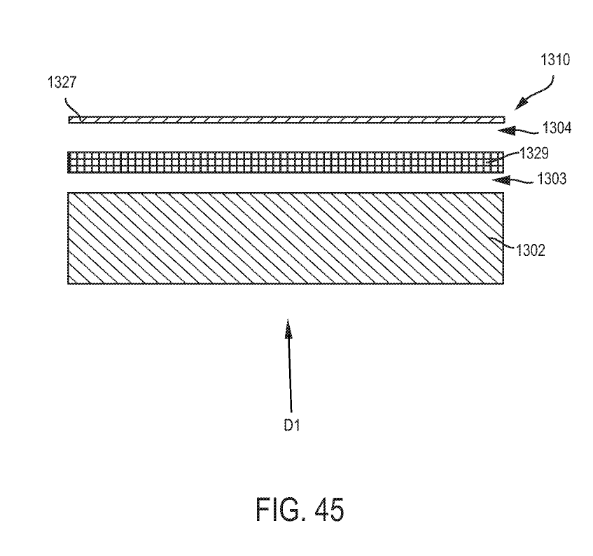

FIGS. 41A and 41B illustrate an embodiment of a second releasable chip 1110 carrier in accordance with one embodiment. The second releasable chip carrier 1110 retains a substrate after the substrate is processed and released from a first panel releasable chip carrier. The second releasable chip carrier 1110 may comprise a strip or panel format. Additionally, the second releasable chip carrier 1110 is configured to retain a thin substrate for electrical/AOI testing prior to assembly. A carrier design structure for the second releasable chip carrier 1110 includes a top plate 1110a and a bottom window plate/frame 1110b that may be attached to or detached from each other by means of slots 1258a and 1258n and a screw mechanism 1271a and 1271n. Additionally, a seal/gasket 1123 is placed on top plate 1110a surrounding metal slabs 1139a and 1139b (comprised by top plate 1110a) and windows 1141a and 1141b to prevent fluids from penetrating windows 1141a and 1141b during a wet processing process. When a substrate is released from a first releasable chip carrier onto the second releasable chip carrier 1110, the transferred substrate is attached to the bottom window frame (i.e., windows 1141a and 1141b). An etching process is required to remove thin copper foil used for making a circuit RDL on the first releasable chip carrier. The seal/gasket 1123 prevents any chemicals from wetting the substrate. After the etching process has concluded, top plate 1110a may be removed to expose the substrate in the windows 1141a and 1141b for electrical testing. Therefore, a two plate design (i.e., top plate 1110a and bottom window plate/frame 1110b) for the second releasable chip carrier 1110 provides support and maintains flatness for a thin substrate during an etching process and subsequent electrical test. FIG. 41A illustrates a top view second releasable chip carrier 1110. FIG. 41B illustrates a side view second releasable chip carrier 1110.

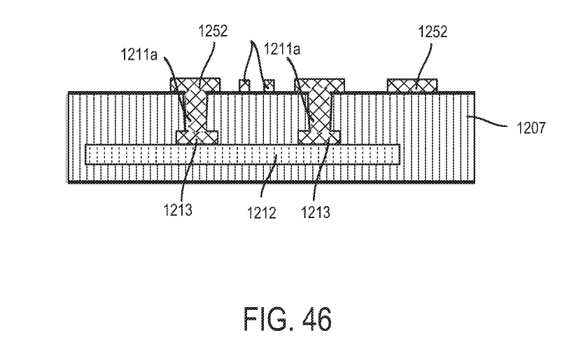

Referring to FIGS. 42A-42L, another embodiment of a fabrication process for making a semiconductor device 1200 (hereinafter described and shown in FIG. 42L) is shown. FIG. 42A depicts a side cutaway view of a step of the fabrication process. In FIG. 42A, the fabrication process is shown to include a step of providing a releasable carrier 1202 that is attached to conductive layers 1201 to create a carrier structure 1210. In the embodiment shown, the conductive layers 1201 include a combination of a first metallic layer 1227 and a second metallic layer 1228. The releasable carrier 1202 may be referred to as a bi-metal carrier. The first metallic layer 1227 and the second metallic layer 1228 are made of different metallic materials such that a first etching interphase 1270 is located between the first metallic layer 1227 and the second metallic layer 1228, and defines where an edge of the metallic material of the first metallic layer 1227 meets an edge of the different metallic material of the second metallic layer 1228. The first metallic layer 1227 may be a thicker conductive layer and the second metallic layer 1228 may be a thin conductive layer. For example, the first metallic layer 1227 may be a thin foil layer such as nickel layer. The second metallic layer 1228 may be a copper layer such as a copper foil layer. The first metallic layer 1227 may be plated onto the second metallic layer 1228. In another embodiment, the first metallic layer 1227 may be an aluminum layer such as an aluminum foil layer. For example, the first metallic material 1227 may be made of aluminum, such as an aluminum foil, and the second metallic layer 1228 may be made of copper.

Each of the first metallic layer 1227 and the second metallic layer 1228 are configured to be chemically etched by different chemical etchants that do not affect the other of the first metallic layer 1227 and the second metallic layer 1228, for example, due to the chemical properties of each of the first metallic layer 1227 and the second metallic layer 1228. As an example, the first metallic layer 1227 is configured such that chemical etchant used to chemically etch the second metallic layer 1228 does not affect the first metallic layer 1227. Likewise, the second metallic layer 1228 is configured such that a chemical etchant used to chemically etch the first metallic layer 1227 does not affect the second metallic layer 1228.

A conductive circuit 1252 (shown in FIG. 42B and described hereinafter) may be applied to a first metallic layer 1227. The first metallic layer 1227 and second metallic layer 1228 are may be chemically etched to form a complete circuit after the releasable carrier 1202 is released (described herein with reference to FIGS. 42H-42J). The conductive circuit 1252 may be configured such that the chemical etchant used to etch the first metallic layer 1227 does not affect the conductive circuit 1252. For example, the second metallic layer 1228 may be copper, and chemically etched using an acidic chemical that does not etch or affect the first metallic layer 1227 which may be aluminum, once the chemical etching of the second metallic layer 1228 reveals the first metallic layer 1227 at the first etching interphase 1270. Further, the first metallic layer 1227 of aluminum may be chemically etched using an alkaline etching chemical that does not affect the copper of the conductive circuit 1252.

The differential etching properties of the first metallic layer 1227, second metallic layer, and conductive circuit 1252 thereby act as a protective etching barrier that prevents over-etching of the first and second metallic layers 1227, 1228 that can cause damage to the conductive circuit 1252, as well as other undesired etching of the first and second metallic layers 1227, 1228. The accuracy of the etching process is thereby improved.

With continuing reference to FIG. 42A, an adhesive layer 1229 is located between the carrier 1202 and the conductive layers 1201. To create or fabricate the carrier structure 1210, the adhesive layer 1229 may be applied to one of the releasable carrier 1202 or the conductive layers 1201 in a first step. The other of the releasable carrier 1202 or the conductive layers 1201 may then be attached. The adhesive layer 1229 may include one or more layers such as a base with adhesive on one or both sides of the base for example, a releasable double-sided tape. The adhesive layer 1229 may be a thermal sensitive adhesive. The thermal sensitive adhesive may be configured to have a reduced adhesive capacity when exposed to high temperatures from, for example, an activating source such as a heat source. The adhesive layer 1229 may be a UV sensitive adhesive, and may be configured to have a reduced adhesive capacity when exposed to an activating source such as a UV light source. In other embodiments, the adhesive layer 1229 may include a different adhesive on each side. For example, the adhesive layer 1229 may be a double-sided tape having two different adhesives, one on each side.

Referring to FIG. 42B, another step in the fabrication process is shown. Once the releasable carrier 1202 has been provided, a substrate 1255 (described hereinafter) may be built upon the releasable carrier 1202 as shown in FIGS. 42B-42F. In the first step of building this substrate 1255, as shown in FIG. 42B, a conductive circuit 1252 may be applied. The conductive circuit 1252 may be a homogeneous copper conductive circuit. In this embodiment, the conductive circuit 1252 is made of a different metallic material than the first metallic layer 1227 such that a second etching interphase 1271 is located between the conductive circuit 1252 and the first metallic layer 1227. The first metallic layer 1227 may be chemically etched using a chemical that does not etch or affect the conductive circuit 1252 at the second etching interphase 1271. For example, the first metallic layer 1227 may be made of a nickel layer, and the conductive circuit 1252 may be a homogeneous copper conductive circuit. The conductive circuit 1252 may be made of the same material as the second metallic layer 1228. The conductive circuit 1252 may be patterned and plated on the first metallic layer 1227. The conductive circuit 1252 may include a plurality of capture pads or die attach pads 1205 and a plurality of traces 1206. The capture pads or die attach pads 1205 and the traces 1206 may each be plated conductive elements. The conductive circuit 1252 may be applied on the first conductive layer 1227 while the releasable carrier 1202 remains attached. The conductive circuit 1252 may include any appropriate conductive elements, portions, or the like. The conductive circuit 1252 may be a redistribution layer (RDL) and may be formed with RDL patterning with semi-additive plating.

Referring to FIG. 42C, another step of the fabrication process is shown. This step includes laminating the conductive circuit 1252 with an insulative material 1207 to encapsulate the conductive circuit 1252. The conductive circuit 1252 may be accordingly referred to as an embedded circuit. The insulative material 1207 may be a photo-imageable dielectric (PID), an ABF film, a mold compound and the like. For example, the insulative material 1207 may be any dielectric material used for creating substrate layers on conductive circuits for semiconductor and printed circuit board (PCB) processes. The insulative material 1207 may have an adjustable thickness depending on the embodiment.

Referring to FIG. 42D, another step of the fabrication process is shown. In this step, the insulation material 1207 may be patterned. The patterning of the insulative material 1207 may include one or more patterned structures 1208a that expose one or more die attach pads or patterned structures 1208b exposing the first metallic layer 1227. A chip 1212 (shown in FIG. 42F) may be placed in this step with solder balls or copper pillars connecting to the circuits 1252 within the patterned structures 1208. Alternatively, the chip 1212 may be placed as shown in FIG. 42F.

Referring to FIG. 42E, another step of the fabrication process is shown in which the patterned structures 1208a, 1208b are filled with conductive material such as copper. In this embodiment, a plurality of copper plated vias 1211a are shown filling the patterned structures 1208a. A copper plated structure 1211b above the unpatterned first metallic layer 1227 is shown filling the patterned structure 1208b. The structures 1211a, 1211b are each flush with the surface of the insulative material 1207, and the completed substrate layer 1255 is defined above the first metallic layer 1227. The substrate 1255 includes a first surface 1256 and a second surface 1257. The embodiment described in FIGS. 42A-42L includes a single substrate 1255, however, the fabrication process is not limited in this regard; for example, multi-layer circuits may be fabricated above substrate layer 1255, for example, by repeating the circuit patterning process using known build up or transfer methods. Before the next step, the electrical and/or mechanical properties of each die attach location may be tested or viewed with a vision system to determine good known die attach locations. The views shown in FIGS. 42A-42L are for a single die attach location, however, in other embodiments, the substrate may continue to the left and right (along with into and out of the page) relative to the cross section shown to provide for additional die attach locations.

Referring to FIG. 42F, a semiconductor die 1212 may then be attached to the second surface 1257 of the substrate layer 1255. The semiconductor die 1212 may be a flip chip or any other type of die and may include interconnects 1212a and 1212b. The die placement and die redistribution of the semiconductor die 1212 may be completed using pick and place tools or other die attach techniques depending on the die pitch design and corresponding registration requirement. Referring to FIG. 42G, another step of the fabrication process is shown in which the semiconductor die 1212 is molded onto the substrate 1255 and the carrier structure 1210 with a mold compound 1214. The molding step may include providing mold compound 1214 under the semiconductor die 1212 such that the mold compound 1214 forms a mold underfill (MUF) in a space between the semiconductor die 1214 and the substrate layer 1255. Mold sheets, powder or liquid molding compounds or systems may be used depending on the package requirements for the mold compound 1214. Capillary underfill (CUF) is also an option rather than MUF. The mold compound 1214 encapsulating the semiconductor die 1212 may be a dielectric material instead of a mold material, for example, ABF film, in other embodiments. Thus, the semiconductor die 1212 may be attached to the substrate 1255 and encapsulated with the mold material 1214 before the releasable carrier 1202 is removed from the substrate 1255 and the conductive layers. The semiconductor may also be encapsulated with a dielectric material such as dielectric material 1207. The conductive circuit 1252 may include a first element 1260 having a first portion such as the structure 1211a in physical contact with the semiconductor die 1212 and at least partially coplanar with the second surface 1257 of the substrate layer 1255 and the insulative material 1207. The first element 1260 may also include a second portion such as the capture pad 1205 that is at least substantially coplanar with the first surface 1256 of the substrate 1255. The first portion and the second portion may have different geometries.

Referring to FIG. 42H, another step of the fabrication process is shown in which the releasable carrier has been released from the conductive layers 1201 and the substrate 1255. The release of the releasable carrier 1202 may be facilitated by an activating source as described hereinabove. Thus, no mechanical peeling may be necessary, and the activating source may reduce the level of adhesive to the point at which the releasable carrier 1202 falls away from the conductive layers 1201 and the substrate 1255. For example, the adhesive layer 1229 may be configured to release the releasable carrier 1202 from the conductive layers 1201 such that the conductive layers 1201 separate from the adhesive layer 1229 without physical contact with the adhesive layer 1229, the releasable carrier 1202, and the conductive layers 1201 by an outside source. The releasable carrier 1202 may be reused to make a second or more semiconductor devices.

Referring now to FIG. 42I, once the releasable carrier 1202 and adhesive layer 1229 are released from the conductive layers 1201, the second metallic layer 1228 may be removed by etching to form an etched layer of the second metallic layer 1227. The second metallic layer 1228 may be removed by chemical etching. The first metallic layer 1227 prevents any over etching by the chemical etching of the second metallic layer 1228 at the first etching interphase 1270 because the second metallic layer 1228 and first metallic layer 1227 are made of different materials with different chemical etching properties, and the first metallic layer 1227 is not affected by the chemical etchant used to chemically etch the second metallic layer 1228. As shown in FIG. 42I, the elements of conductive circuit 1252 are protected on all sides or surface portions of the elements of conductive circuit 1252 during the etching process to prevent over-etching For example, an element 1252e of conductive circuit 1252 is shown having a first side 1401, which is protected during the etching process by the first metallic layer 1227, which has different chemical etching properties than the element 1252e such that conductive circuit 1252 is not affected by the chemical etchant used to chemically etch the first metallic layer 1227. The conductive circuit element 1252e has a second side 1402, third side 1403, and a fourth side 1404 that are protected by the insulative material 1207.

Referring to FIG. 42J, once the second metallic layer 1228 has been etched, the first metallic layer 1227 may be etched, for example, by chemical etching, to expose the embedded conductive circuit 1255 in the insulative material 1207 to form a complete circuit. The embedded conductive circuit 1252 may have a thickness of less than or equal to 2 μm, or as little as 1 μm or less. In some embodiments, only a portion of a conductive circuit may be embedded in the substrate 1255. In some embodiments, a portion of a conductive circuit embedded in the substrate 1255 may have a thickness of less than or equal to 2 μm or as little as 1 μm or less. As the first metallic layer 1227 and the conductive circuit 1252 are made of different materials each having different chemical etching properties, the chemical etching of the first metallic layer 1227 will not over-etch onto the conductive circuit 1252 at the second etching interphase 1271 because the conductive circuit 1252 is not affected by the chemical etchant used to chemically etch the first metallic layer 1227.

Referring to FIGS. 42K and 42L, the recessed embedded circuit 1252 may form an opening for a ball grid array (BGA) ball attach process for completing the semiconductor device 1200. In FIG. 42K, the etched circuit may include solder ball attach locations 1217 without solder masks for attachment to solder balls 1218. In FIG. 42L, the etched include solder mask defined (SMD) BGA ball attach. In particular, a solder mask material 1219 may be applied in a manner creating a defined opening 1220 for the solder balls 1218.

A semiconductor device may thereby be fabricated to include a semiconductor die 1212 attached to the second surface 1257 of the substrate 1255, the substrate 1255 having a layer of insulative material 1207, at least a portion of a conductive circuit 1252 in the layer of insulative material 1207 and located on the first surface 1256 of the substrate 1255, and an etched layer of conductive material such as first metallic layer 1227 and/or second metallic layer 1228 attached to the conductive circuit 1252. The etched layer of conductive material, such as first and or second metallic layers 1227, 1228 and the conductive circuit may be made of different metallic materials. In some embodiments, a conductive circuit redistribution layer may be patterned before and after the releasable carrier 1202 is removed. This may be referred to as top and bottom build up.

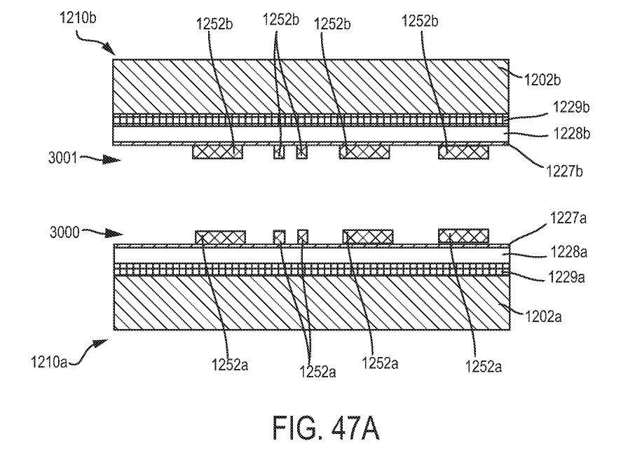

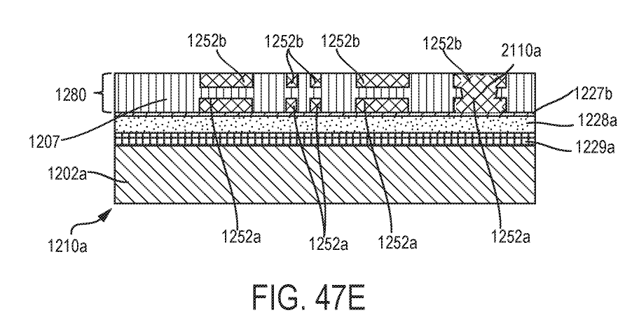

In another embodiment of a fabrication process for the creation or fabrication of a semiconductor device, a releasable carrier 1302 may be provided having a single metallic layer, such as first metallic layer 1327 as shown in FIG. 43. To create or fabricate the carrier structure 1310, an adhesive layer such as adhesive layer 1229 may be applied to one of the releasable carrier 1302 or the first metallic layer 1327 in a first step. The other of the releasable carrier 1302 or first metallic layer 1327 may then be attached. A conductive circuit such as conductive circuit 1252 may be patterned and plated on the first metallic layer 1327. The conductive circuit may be made of a different material than the first metallic layer 1327 such that an etching interphase 1370 is located in between the first metallic layer 1327 and the conductive circuit. For example, the first metallic layer 1327 may be a nickel or aluminum layer, and the conductive circuit may be a homogeneous copper conductive circuit, such that the first metallic layer 1327 and the conductive circuit have different etching properties such that the chemical etchant used to chemically etch the first metallic layer 1327 does not affect the conductive circuit. The conductive circuit is thereby protected from over-etching and damage caused by over-etching. The single metallic layer embodiment may be used in the multiple carrier process described with respect to FIGS. 46A-46G.

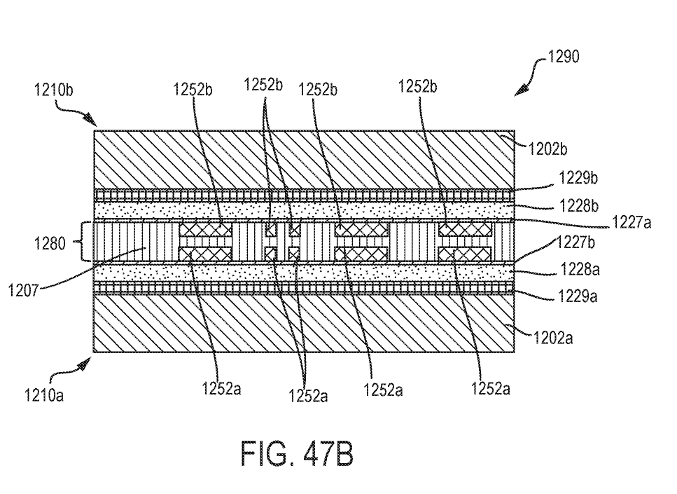

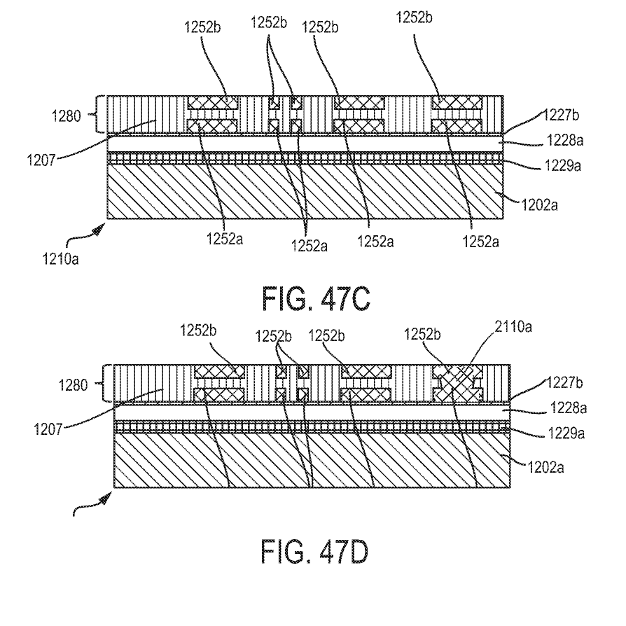

Referring to FIG. 44, an exploded view of the releasable carrier 1202 shown in FIG. 42A is shown. In this embodiment, the releasable carrier 1202, adhesive layer 1229, and first and second metallic layers 1227, 1228 form a first release point 1300 between the releasable carrier 1202 and the adhesive layer 1229, a second release point 1301 between the adhesive layer 1229 and the second metallic layer 1228, and a third release point 1302 between the second metallic layer 1228 and the first metallic layer 1227. An activating source configured to activate release by the adhesive layer 1229 may be directed to the carrier structure 1210 in direction D1. Referring to FIG. 45, an exploded view of the releasable carrier 1302 in FIG. 43 is shown. In this embodiment, the releasable carrier 1302, adhesive layer 1229, and the first metallic layer 1327 form a first release point 1303 between the releasable carrier 1302 and the adhesive layer 1229, and a second release point 1304 between the adhesive layer 1229 and the first metallic layer 1327. An activating source configured to activate release by the adhesive layer 1229 may be directed to the carrier structure 1310 in direction D1.

Referring to FIG. 46, a side cutaway view of a step of a fabrication is shown according to another embodiment. As shown, a semiconductor die 1212 has been encapsulated in a dielectric material 1207. This embodiment may be referred to as “die up.” The orientation of the semiconductor die 1212 in FIGS. 42F-42L, for example, may be referred to as “die down.” The semiconductor die 1212 is facing up, with die pads 1213 on the top-most surface of the semiconductor die 1212. A via may be formed in the dielectric material 1207 such that a conductive element 1211a may be formed extending from the die pad. A semi-additive process may be used to build an RDL layer including a conductive circuit 1252. Thereafter, additional embedded circuit RDL layers may be formed. In one embodiment, a releasable carrier may be used when encapsulating the semiconductor die 1212 in a dielectric material. The dielectric material may be a photo-imageable dielectric material. Vias may be formed in the dielectric material and plated up. Solder balls may then be attached, and the carrier removed. Die up or die down methods may be used in a fabrication process.

An embodiment of a method for making a semiconductor device, such as semiconductor device 1200, may include patterning a conductive circuit, such as conductive circuit 1252, on at least one conductive layer, such as the first metallic layer 1227, 1327 and second metallic layer 1228, and applying an insulative material such as insulative material 1207 over the conductive circuit to create a substrate having a first surface, such as first surface 1256, and a second surface such as second surface 1257. The method may further include attaching a semiconductor die 1212 to the second surface of the substrate and etching the conductive layer. The method may further include providing a releasable carrier such as releasable carrier 1202, 1302 attached directly or indirectly to the conductive layer. The method may include plating the conductive layer on a second conductive layer such that the second conductive layer is located on the first surface, etching the second conductive layer. The method may include operationally testing the substrate, for example, before attaching the semiconductor die to the second surface of the substrate.

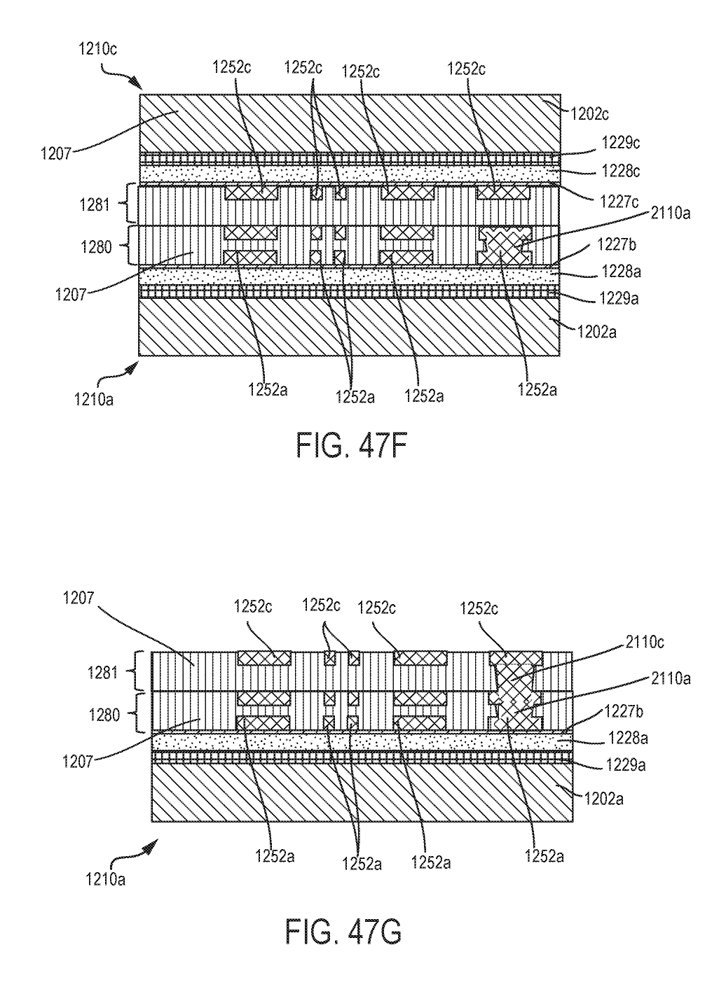

In another embodiment, multiple fine line RDL layers may be formed using multiple releasable carriers. Multiple RDL layers may be formed using multiple carriers before a semiconductor die is attached, for example, after the step of the fabrication process shown in FIG. 42E. With reference to FIGS. 46A-46G, a multiple fine line RDL layer formation process is shown using multiple releasable carriers. The use of multiple carriers allows for fine line RDL layers, as the layers may be transferred from one carrier to another, and at any time in the process. Referring to FIG. 47A, a first carrier structure 1210a and a second carrier structure 1210b are shown. The first carrier structure 1210a includes a first releasable carrier 1202a, an adhesive layer 1229a, a first metallic layer 1227a and a second metallic layer 1228a. The first releasable carrier 1202a has a first RDL layer 3000 including a conductive circuit 1252a. In other embodiments, the first carrier structure 1210a may have a conductive circuit 1252a with a bi-metal structure, for example, as described above with respect to FIGS. 27 and 28, instead of or in addition to the first and second metallic layers 1227a, 1228a. For example, the conductive circuit 1252a may have a nickel layer and a copper layer. The second carrier structure 1210b includes second releasable carrier 1202b, an adhesive layer 1229b, a first metallic layer 1227b and a second metallic layer 1228b. The second releasable carrier 1202b has a second RDL layer 3001 including a conductive circuit 1252b. In other embodiments, the second carrier structure 1210b may have a conductive circuit 1252b with a bi-metal structure, for example, as described above with respect to FIGS. 27 and 28, instead of or in addition to the first and second metallic layers 1227b, 1228b. For example, the conductive circuit 1252b may have a nickel layer and a copper layer. The first releasable carrier 1202a and second releasable carrier 1202b may each be a glass carrier, a metal core carrier, a clad core carrier, a laminate carrier, an aluminum carrier, a copper carrier, or a stainless steel carrier, an organic reinforced core carrier a ceramic material or combinations thereof.

To build the multiple RDL layers, as shown in FIG. 47B, the conductive circuit 1252a of the first RDL layer 3000 and the conductive circuit 1252b of the second RDL layer 3001 are embedded in a dielectric material 1207 to form a dielectric layer 1280. The first releasable carrier 1202a and the second releasable carrier 1202b may have corresponding tooling holes through which pins may be inserted to align the first releasable carrier 1202a and second releasable carrier 1202b. A dielectric material 1207 may then be applied, for example, a film, prepreg, or liquid spin-on dielectric material. As an example, liquid dielectric material 1207 may be applied, for example, using a spin coat. As another example, the dielectric material 1207 may be a film, and may be applied to the first releasable carrier 1202a, and the second releasable carrier 1202b may be lowered onto the first carrier structure 1210a such that the conductive circuits 1252a and 1252b are embedded in the dielectric material 1207. The dielectric material 1207 may then be laminated and heated such that the dielectric material 1207 is cured. A multiple carrier structure 1290 is thereby formed.

Next, as shown in FIG. 47C, the second releasable carrier 1202b is removed. The second releasable carrier 1202b may be removed by an activating source as aforementioned such as heat or UV. The second metallic layer 1228b may be removed, exposing the first metallic layer 1227b, and the first metallic layer 1227b may be etched for example, by a differential chemical etch as described above with respect to FIGS. 42I and 42J. During the etching process, the conductive circuit 1252b is protected on all sides by the differential etch characteristics of the first metallic layer 1227b and the conductive circuit 1252b, as well as by being embedded in the dielectric layer 1280. As shown in FIG. 47C in the dielectric layer 1280, the conductive circuit 1252a is adjacent to a first surface 3010 of the dielectric layer 1280, and the conductive circuits 1252b is adjacent to a second surface 3011 of the dielectric layer 1280. The conductive circuits 1252a and 1252b are in plane, inside of the dielectric layer 1280. As shown in FIG. 47D, a portion of the dielectric material 1207 may be removed, for example, by laser ablate, exposing capture pads, and a copper plated filled via 2110a may be formed thereby connecting the conductive circuit 1252a to the of the conductive circuit 1252b. Interconnection between each RDL circuit layer may be accomplished with conductive metal structures such as copper plated filled vias, through holes, and plated blind vias. The via connections between the conductive circuits 1252a and 1252b are based on the size of the capture pads. As an example, a via that is 10 μm wide may correspond to a capture pad that is 16 μm across, leaving 6 μm of extra space on the capture pad to position the via. Copper pillars may be formed through multiple RDL layers. One or more vias may be formed through the RDL layers to the first metallic layer 1227 and one or more copper pillars, or other metallic pillars may be formed in the one or more vias by plating copper or other metal. For example, one or more copper pillars may be formed to extend from the first metallic layer 1227a to the surface of the RDL layer farthest from the first carrier 1202a, and the first metallic layer 1227 may be eventually etched such that the etched layer of the first metallic layer 1227 forms pads under the copper pillars, such as copper foil pads.

With reference to FIG. 47E, a third carrier structure 1210c may be used to form another RDL layer above the second RDL layer 3001. The third carrier structure 1210c includes a third releasable carrier 1202c, an adhesive layer 1229c, a first metallic layer 1227c and a second metallic layer 1228c, and a third RDL layer 3002 including a conductive circuit 1252c. In other embodiments, the third carrier structure 1210c may have a conductive circuit 1252c with a bi-metal structure, for example, as described above with respect to FIGS. 27 and 28, instead of or in addition to the first and second metallic layers 1227c, 1228c. For example, the conductive circuit 1252c may have a nickel layer and a copper layer. The conductive circuit 1252c may include capture pads.

As shown in FIG. 47F, the third RDL layer 3002 may be attached to dielectric layer 1280 such that the conductive circuit 1252c is embedded in dielectric material 1207 to form another dielectric layer 1281 on top of the dielectric layer 1280. Dielectric layer 1281 may be formed in the same manner as described above with respect dielectric layer 1280 such that the conductive circuit 1252c is embedded in the dielectric layer 1281. The dielectric material 1207 of dielectric layer 1281 may be laminated and heated such that the dielectric material 1207 is cured resulting in the formation of multiple carrier structure 1291.

In this embodiment, as shown in FIG. 47F, additional RDL layers such as the third RDL layer 3002, a fourth RDL layer, and so on, are embedded sequentially one after another, whereas the first and second RDL layers 3000 and 3001 are embedded at the same time as shown in FIG. 47B. As shown in FIG. 47B, the conductive circuit 1252a is embedded in the dielectric layer 1280 adjacent to the first surface 3010, and the conductive circuit 1252b is embedded in the same dielectric layer 1280 adjacent to the second surface 3011. Each dielectric layer may have the same thickness, or a different thickness depending on the electrical design requirements. Further, each dielectric layer may be made of the same dielectric material. Each dielectric layer may be made out of a different dielectric material. A number of dielectric layers may be made of the same dielectric material, and a number of dielectric layers may be made out of a different dielectric material.

With reference to FIG. 47G, the third releasable carrier 1202 is removed, for example, by an activating source aforementioned such as heat or UV. The second metallic layer 1210c may be removed exposing the first metallic layer 1227c, and the first metallic layer 1227c may be etched for example, by a differential chemical etch as described above with regard to FIGS. 42I and 42J. During the etching process, the conductive circuit 1252c is protected by differential etch characteristics of the first metallic layer 1227c and the conductive circuit 1252c, as well as being embedded in the dielectric layer 1281. As shown in FIG. 47G, a portion of the dielectric material 1207 may be removed, for example, by laser ablate, exposing capture pads, and a copper plated filled via 2110b may be formed thereby connecting the conductive circuit 1252b to the conductive circuit 1252c.

The steps shown in FIGS. 47E-47G may be repeated with a fourth carrier structure, a fifth carrier structure, and so to form as many RDL layers as desired. Each embedded conductive circuit may include traces having a line dimension and a space dimension that are equal to or less than 2 μm/2 μm line and space, or as little as 1 μm/1 μm or less line and space. Each embedded conductive circuit may have a fine pitch between capture pads that is enabled by the fine line and space of the traces.

Once the desired number of RDL layers are formed, and before a semiconductor is attached, the RDL layers may undergo electrical testing to ensure that the circuitry is operational, and ensure that during a subsequent assembly process a semiconductor die is only attached to good known substrate. For example, after the step shown in FIG. 47G, the first releasable carrier 1202a may be removed, and the second metallic layer 1228a may be removed exposing the first metallic layer 1227a, and the first metallic layer 1227a may be etched. During the etching process, the conductive circuit 1252a is protected by differential etch characteristics of the first metallic layer 1227a and the conductive circuit 1252, as well as being embedded in the dielectric layer 1280. Prior to die attachment, the RDL layers may be transferred to a frame carrier, and the first carrier 1202a may be removed, such that the RDL layers may undergo electrical testing. The RDL layers may be be probed from the top of the RDL layers or the bottom of the RDL layers during electrical testing. After electrical testing and a determination that the circuitry is operational, the RDL layers may be transferred to another releasable carrier to undergo an assembly process. For example, a semiconductor die such as semiconductor die 1212 may be attached, and encapsulated. The carrier may then be removed and further assembly such as a ball attach process may be completed. In another embodiment, a semi-additive process may be used to form additional RDL layers before the semiconductor die 1212 is attached, for example, using the process shown in FIG. 17.

In another embodiment, the steps shown in FIGS. 46A-46G may be repeated with additional carriers to form a second structure that includes embedded conductive circuit layers in a dielectric material such as dielectric layers 1280 and 1281 shown in FIG. 47G. The second structure may then be stacked on the dielectric layer 1280 shown in FIG. 47G and connected thereto, for example, using solder balls, copper pillars, or a combination of solder balls and copper pillars. Additional structures may be formed, stacked, and connected in the same manner, and electrical testing may be performed to ensure that the circuitry is operational, and ensure that during a subsequent assembly process a semiconductor die is only attached to good known substrate.

In yet another embodiment, the steps shown in FIGS. 47A through 47D may be repeated to create a second layer having a conductive circuit of a third RDL layer and a conductive circuit of a fourth RDL layer both embedded in the same layer of dielectric material, the way that conductive circuits 1252a and 1252b are shown in the dielectric layer 1280 in FIG. 47D. This second layer may be stacked on the layer 1280 shown in FIG. 47D, for example, by copper pillars or solder balls. A third layer, fourth layer, fifth layer, and so on having the circuit patterns from two RDL layers embedded in a single dielectric layer may be formed, stacked, and connected as well.

In another embodiment, the first metallic layer 1227 may be a copper foil layer having a thickness configured such that the copper foil layer may be patterned to make a ground plane or a power plane. In this embodiment, the ground plane or power plane may be patterned such that the conductive circuits such as conductive circuits 1252a of an RDL layer built upon the copper foil layer may still be exposed to complete the conductive circuit 1252a. For example, a ground plane or power plane may be patterned around the conductive circuit 1252a where the copper foil layer does not need to be etched away to complete the conductive circuit 1252. Using a copper foil layer or other metallic layer having a thickness configured such that the copper foil layer or other metallic layer may be patterned to make a ground plane or a power plane may be used instead of using sputter or electroless copper and electrolytic copper to thicken a copper layer for a ground or power plane. Further, such a copper foil layer may provide enhanced structural integrity and warpage control. In the process shown in FIGS. 46A-46G for example, one or more of the releasable carrier used may include a copper foil layer or other metallic layer configured to be patterned to make a ground plane or power plane. In another embodiment, a copper foil layer may be used to create a split power and ground plane. A copper foil layer configured to be patterned to create a power plane or ground plane may be used for plating copper pillars to connect RDL layers. For example, a hole may be formed through RDL layers formed on a first releasable carrier 1252a to a first metallic layer 1227, the first metallic layer 1227 being configured to be patterned to create a power plane or a ground plane, and a copper pillar may be plated in the hole from the first metallic layer 1227 such that the first metallic layer forms a copper foil pad for the copper pillar.

Multiple RDL layers may also be formed using the molded die-to-carrier process described with respect to FIGS. 13-16. For example, at the step of the multiple RDL layer formation process shown in FIG. 47A, the conductive circuit 1252a on the first releasable carrier 1202a may be embedded in a dielectric material 1207, and copper plated filled vias may be formed in the dielectric material 1207 after the dielectric material 1207 is cured to form a first dielectric layer. A semiconductor die may then be attached to circuit pads at the copper plated filled vias, and the semiconductor may be molded with a mold compound, before additional RDL layers are formed. The semiconductor may also be encapsulated with a dielectric material such as dielectric material 1207. Next, the first releasable carrier 1202a may be removed, the second metallic layer 1228a may be removed to expose the first metallic layer 1227a, and the first metallic layer 1227a may be etched to expose the embedded RDL conductive circuit 1252a. A second carrier structure such as second carrier 1210b may then be used for form additional RDL layers. The second releasable carrier structure 1210b may include the second releasable carrier 1202b, adhesive layer 1229b, first metallic layer 1227b, second metallic layer 1228b, and second RDL layer 3001 including the conductive circuit 1252b. One or more above-plane circuits such as above-plane circuits 204 shown in FIG. 13 may be placed on the first dielectric layer before an additional RDL layer is formed thereon. To apply the next RDL layer, the conductive circuit 1252b may be embedded in dielectric material 1207 on the first dielectric layer to create another dielectric layer upon the first dielectric layer. Any above-plane circuits applied to the first dielectric layer may be embedded in the dielectric material 1207 with the conductive circuit 1252b as well. During this process, in this embodiment, the molded semiconductor die layer may act as the structural support upon which to build additional layers. The dielectric material 1207 may then be laminated and heated such that the dielectric material 1207 is cured forming the second dielectric layer. The second releasable carrier 1202b may then be removed. The second metallic layer 1210b may be removed exposing the first metallic layer 1227b, and the first metallic layer 1227b may be etched. A portion of the dielectric material 1207 in which the conductive circuit 1252b are embedded may be removed, for example, by laser ablate, exposing capture pads, and a copper plated filled via 2110b may be formed thereby connecting the conductive circuit 1252a to the conductive circuit 1252b. This process may be repeated to form the desired number of RDL layers, by using the molded semiconductor die as the first releasable carrier 1202a, and by using a third releasable carrier, fourth releasable carrier, fifth releasable carrier, and so on. Electrical testing may also be performed before an assembly process, such as die attachment.

In some embodiments, a fabrication process may include forming multiple RDL layers, attaching a semiconductor die, and forming additional RDL layers on top of the semiconductor die. Forming the additional RDL layers may include semi-additive build up and embedded RDL layers.

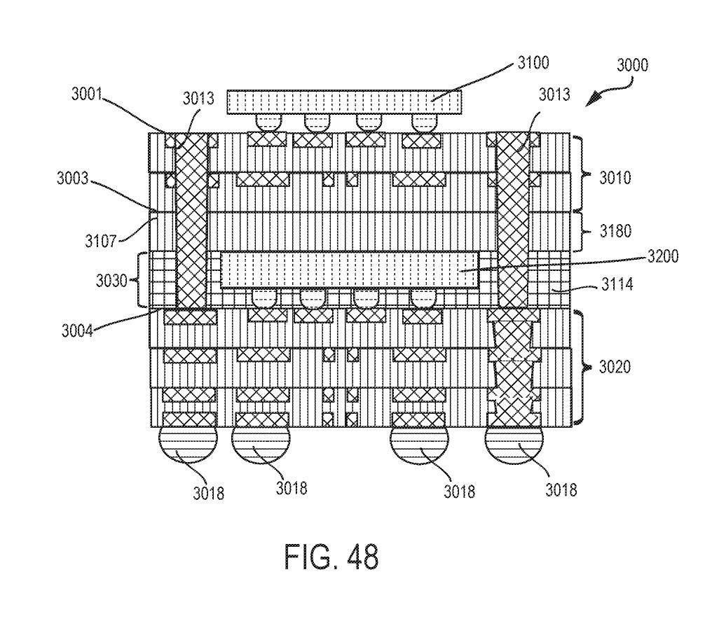

Different package types may be formed using multiple carriers such as releasable carriers 1202a, 1202b, and 1202c to create multiple RDL layers in a package structure as shown in FIGS. 46A-46G. For example, multiple carriers may be used to form a package on package (PoP) structure. A PoP structure may include multiple active and passive dies. The use of multiple releasable carriers enables electrical testing of the RDL layers prior to die attachment. In a PoP structure, the packages may be connected by interconnects, for example, solder balls or copper pillars. For example, a PoP structure may have two interposers, and a copper pillar may extend from the first metallic layer of the first interposer, through the RDL layers of the first interposer, and extend through the second interposer and the RDL layers of the second interposer such that both interposers in the PoP structure share a copper pillar. For example, interconnects may be formed by metal plating. As an example, this may be done by forming a via through RDL layers to the first metallic layer 1227a on the first carrier 1202a, and metal plating from the first metallic layer 1227a through the first the via to the surface of the RDL layer farthest from the first carrier 1202a to form a copper pillar. A via or hole may be formed such that the first RDL layer and last RDL layer such that copper plating may be performed from the first RDL layer to the last RDL layer. Copper pillars may have a high aspect-ratio, namely, a greater height than width, to connect a package to another package. As further examples, the multiple carrier method shown in FIGS. 47A to 47G may be used to form a system in package (SiP), and 2.3D package architectures. Referring to FIG. 48, an embodiment of a PoP structure 3000 is shown. PoP structure 3000 has a top interposer 3010 and a bottom substrate 3020. The top interposer 3010 and bottom substrate 3020 may both be referred to as substrates and interposers. In the embodiment shown, a memory die 3100 is attached to top interposer 3010. Top interposer 3010 includes multiple RDL layers. Bottom substrate 3020 includes multiple RDL layers. The number of RDL layers shown in the top interposer 3010 and bottom substrate 3020 may be different than that shown in FIG. 48, and each of the top interposer 3010 and bottom substrate 3020 may one or more layers depending on the design desired. Between the top interposer 3010 and the bottom substrate 3020 is a semiconductor die 3200 encapsulated in a mold material 1214. The encapsulated semiconductor die 3200 and the mold material 1314 form a mold layer 3030. In the embodiment shown, the semiconductor die 3200 is in a die down orientation. A layer of insulative material such as a dielectric layer 3180 is located above the mold layer 3030. Extending through the mold layer 3030 and through the top interposer 3010 are copper pillars 3013. While two copper pillars 3013 are shown, a PoP structure may have multiple rows of copper pillars connecting the bottom substrate 3020 and top interposer 3010. A PoP structure may include more than one semiconductor die. For example, a PoP structure may include a semiconductor die located above another semiconductor die. As another example, a PoP structure may include two or more semiconductor dies positioned side by side.

To create the PoP structure 3000, the bottom substrate 3020 may be formed, to include as many RDL layers are needed. For example, multiple RDL layers may be formed using the process shown in FIGS. 47A-47G to create the bottom substrate. The RDL layers of the bottom substrate 3020 may be transferred to a frame carrier to be electrically tested, and then transferred to another releasable carrier. Next, copper pillars may be plated on a top surface 3004 of the top RDL layer of the bottom substrate 3020. The copper pillars may be plated on copper foil on the top RDL layer of the bottom substrate 3020, such as copper foil pads. The semiconductor die 3200 may be attached to the top RDL layer of the bottom substrate 3020, and the semiconductor die 3200 and copper pillars may then be encapsulated with a mold material 1214. A dielectric material may be used to encapsulate the copper pillars and the semiconductor die. A mold material 1214 may easily encapsulate the copper pillars and semiconductor die 3200, for example, such that the mold material flows around the copper pillars and under the semiconductor die 3200. The mold layer 3030 may then undergo mechanical planarization such as grinding, to expose the copper pillars. The height of the copper pillars at this step may be above or below the level of the semiconductor die 3200. The grinding or thinning down of the mold layer 3030 may be done such that the semiconductor die 3200 is exposed as well as the copper pillars, and such that the semiconductor die 3200 may be grinded or thinned down in order to reduce the thickness of the semiconductor die 3200. In another embodiment, the top surface of the semiconductor die 3200 may be lower than top of the copper pillars in the mold layer 3030.

The top interposer 3010 may be formed by forming however many RDL layers are required. For example, the top interposer may be formed on a second releasable carrier using the multiple RDL multiple releasable carrier method shown in FIGS. 47A to 47G. The conductive circuits of the RDL layers of the top interposer 3010 may connected, for example, by copper plated filled vias such as 2110a such that the RDL layers of the top interposer 3010 may undergo electrical testing before being placed on the mold layer 3030. In some embodiments, the conductive circuits of the RDL layers of the top interposer 3010 may not be connected before being placed on the mold layer 3030 and may undergo automatic optical inspection instead.

A dielectric layer 3180 may be used to attach the top interposer 3010 to the mold layer 3030. In the embodiment shown the dielectric layer 3180 is a laminated dielectric material such as dielectric material 1207. Next, the top interposer 3010 may be interconnected to the bottom substrate 3020. For example, copper pillars 3013 may be made by forming holes that extend from the mold layer 3030 copper pillars to the top surface 3001 of the top RDL layer of the top interposer 3010, and plating up copper pillars 3013 such that the bottom substrate 3020 is connected to the top interposer 3010. The top interposer 3010 and bottom substrate 3020 may be interconnected by a semi-additive metallization process.

In other embodiments, the top interposer 3010 may be formed using a semi-additive process. For example, the dielectric layer 3180 may be laminated on the molded layer 3030, vias may be drilled in the dielectric layer 3180 to connect to the copper pillars, and the top interposer 3010 may be formed by building up RDL layers on the surface 3003 of the dielectric layer 3180 using a semi-additive process.

The releasable carrier supporting the bottom substrate 3020 may be removed, and an adhesive layer of the releasable carrier may be removed. One or more metallic layers such as a copper foil layer of the releasable carrier may be etched. The memory die 3100 may be attached and BGA balls 3018 may also be attached.

In another embodiment, the bottom substrate 3020 and top interposer 3010 may be interconnected by solder balls. In yet another embodiment, the copper pillars formed on the top surface 3004 of the top RDL layer of the bottom substrate 3030 may have tin or other solder material plated on top such that when the molded layer 3030 is mechanically planarized, the solder material on the copper pillars is exposed. In this embodiment, the top interposer may be formed such that the top interposer has copper pins aligned to correspond to the solder material on the copper pillars in the molded layer 3030, and such that the copper tips may be connected to the solder material on the copper pillars.

In embodiments in which the RDL layers of one or more of the top interposer 3010 and bottom substrate 3020 include fine line circuits, for example, 2 μm/2 μm line and space, in one or more RDL layers, and larger circuit features in one or more other RDL layers, a combined embedded with semi-additive conductive circuit processing method may be used. For example, the fine line circuit layers may be embedded, as shown for example with respect to conductive circuit element 1252e in FIG. 42I in FIGS. 4, and the larger conductive circuit feature layers may be formed using a semi-additive process.

Elements of the embodiments have been introduced with either the articles “a” or “an.” The articles are intended to mean that there are one or more of the elements. The terms “including” and “having” and their derivatives are intended to be inclusive such that there may be additional elements other than the elements listed. The conjunction “or” when used with a list of at least two terms is intended to mean any term or combination of terms. The terms “first” and “second” are used to distinguish elements and are not used to denote a particular order.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

What is claimed is:

1. A semiconductor device comprising:
a semiconductor die; and
a substrate having a first surface and a second surface,
wherein the semiconductor die is attached to the second surface, the substrate including a layer of insulative material and an embedded conductive circuit in the layer of insulative material,
wherein the embedded conductive circuit includes an etched layer of a conductive material, the etched layer of the conductive material located on the first surface of the substrate, and
wherein the etched layer of the conductive material is made of a first metallic material and the at least a portion of the embedded conductive circuit is made of a second metallic material that is different than the first metallic material.

2. The semiconductor device of claim 1, further comprising a second etched layer of conductive material, wherein the etched layer of a conductive material is plated on the second etched layer of conductive material, wherein the second etched layer of conductive material is made of a third metallic material that is different than the first metallic material.

3. The semiconductor device of claim 1, wherein the second metallic material is a homogenous metal.

4. The semiconductor device of claim 1, wherein the second metallic material is copper.

5. The semiconductor device of claim 1, wherein the at least a portion of the embedded conductive circuit has a thickness of less than or equal to 2 μm.

6. The semiconductor device of claim 1, wherein the layer of insulative material is a dielectric material.

7. The semiconductor device of claim 2, wherein the second metallic material and the third metallic material are the same.

8. The semiconductor device of claim 2, wherein the first metallic material is at least one of the group comprising nickel and aluminum, the second metallic material is copper, and the third metallic material is copper.

9. The semiconductor device of claim 2, wherein the second etched layer of the conductive material is a metal foil.

10. The semiconductor device of claim 2, wherein the at least a portion of the embedded conductive circuit has a thickness of less than or equal to 2 μm.

11. The semiconductor device of claim 1, wherein the substrate includes a portion of the embedded conductive circuit adjacent to the second surface.

12. The semiconductor device of claim 1, further comprising
a second substrate having a third surface adjacent to the first surface, and a fourth surface, wherein the second substrate comprises:
a second layer of insulative material;
a first conductive circuit layer adjacent to the third surface and embedded in the second layer of insulative material; and
a second conductive circuit layer adjacent to the fourth surface and embedded in the second layer of insulative material.

13. The semiconductor device of claim 12, wherein the insulative layer is a first dielectric material, wherein the second insulative layer is a second dielectric material, wherein the first dielectric material and the second dielectric material are different.

14. The semiconductor device of claim 12, including at least one copper pillar extending from the etched layer of conductive material through the substrate and second substrate.

15. The semiconductor device of claim 1, further comprising a plurality of traces having a line dimension and space dimension, wherein each of the line dimension and space dimension is 2 μm or less.

16. A method of making a semiconductor device comprising:
patterning a conductive circuit on a conductive layer;
applying an insulative material over the conductive circuit to create a substrate having a first surface and a second surface, wherein the conductive layer is located on the first surface;
attaching a semiconductor die to the second surface of the substrate; and
etching the conductive layer,
wherein the conductive layer is made of a first metallic material and the conductive circuit is made of a second metallic material that is different than the first metallic material.

17. The method of making a semiconductor device of claim 16, further comprising providing a releasable carrier attached directly or indirectly to the at least one conductive layer.

18. The method of making a semiconductor device of claim 16 further comprising:
plating the conductive layer on a second conductive layer such that the second conductive layer is located on the first surface; and
etching the second conductive layer,
wherein the second conductive layer is made of a third metallic material that is different than the first metallic material.

19. The method of making a semiconductor device of claim 16, wherein the conductive layer is a metal foil.

20. The method of making a semiconductor device of claim 16, wherein the first metallic material is at least one of nickel and aluminum.

21. The method of making a semiconductor device of claim 18, wherein the first metallic material is at least one of nickel and aluminum, the second metallic material is copper, and the third metallic material is copper.

22. The method of making a semiconductor device of claim 16, wherein the first metallic material and the second metallic material are each configured such that chemical etching of the first metallic material does not affect the second metallic material.

23. The method of making a semiconductor device of claim 18, wherein the first metallic material, the second metallic material, and the third metallic material are each configured such that chemical etching of the third metallic material does not affect the first metallic material and such that chemical etching of the first metallic material does not affect the second metallic material.

24. The method of making a semiconductor device of claim 16, wherein the conductive circuit is a homogeneous metal.

25. The method of making a semiconductor device of claim 18, wherein the insulative material is applied such that all surface portions of the conductive circuit are protected by at least one of the insulative material and the conductive layer such that the conductive circuit is not affected by over etching during the etching the conductive layer and the etching the second conductive layer.

26. The method of making a semiconductor device of claim 16, further comprising
patterning a conductive circuit layer on a second conductive layer; and
etching the second conductive layer,
wherein the applying an insulative material over the conductive circuit to create a substrate having a first surface and a second surface includes applying the insulative material over the conductive circuit layer such that the conductive layer is located on the first surface and the second conductive layer is located on the second surface, and
wherein the second conductive layer is made of a third metallic material and the conductive circuit layer is made of a fourth metallic material that is different than the third metallic material.

27. The method of making a semiconductor device of claim 26, further including
providing a first carrier including a first releasable adhesive and the conductive layer on the first releasable adhesive;
providing a second carrier including a second releasable adhesive and the second conductive layer on the second releasable adhesive;
releasing the first carrier and first releasable adhesive from the conductive layer; and
releasing the second carrier and second releasable adhesive from the conductive layer.

28. The method of making a semiconductor device of claim 16, further including operationally testing the substrate.

29. The method of making a semiconductor device of claim 28, wherein the operationally testing the substrate is performed before the attaching a semiconductor die to the second surface of the substrate.

30. The method of making a semiconductor device of claim 16, further including
encapsulating the semiconductor die in a mold material to create a molded layer;
forming a dielectric layer on the molded layer;
providing a second substrate on the dielectric layer such that the molded layer is between the first and second substrates, wherein the second substrate includes a conductive circuit layer; and
interconnecting the substrate and second substrate.

31. The method of making a semiconductor device of claim 30, further including thinning the semiconductor die in the molded layer.

32. A semiconductor device comprising:
a first substrate including a layer of insulative material and an embedded conductive circuit layer in the layer of insulative material;
a second substrate including a second layer of insulative material and a conductive circuit layer in the second layer of insulative material; and
an encapsulated semiconductor die located between the first substrate and the second substrate;
a layer of insulative material located between the encapsulated semiconductor die and the second substrate,
wherein the first substrate and second substrate are interconnected.

33. The semiconductor device of claim 30, wherein the encapsulated semiconductor die is encapsulated in a mold material.

34. The semiconductor device of claim 31, wherein the mold material forms a mold layer, wherein the mold layer includes at least one copper pillar.

35. The semiconductor device of claim 32, wherein the at least one copper pillar extends from the mold layer and through the second substrate.

36. The semiconductor device of claim 30, further comprising a memory die.

37. The semiconductor device of claim 30, wherein the first substrate further includes a first etched layer of a conductive material attached to the embedded conductive circuit layer, wherein the second substrate further includes a second etched layer of a second conductive material attached to the conductive circuit layer.

38. The semiconductor device of claim 37, wherein the embedded conductive circuit layer and the conductive circuit layer are each made of a homogenous metal, wherein the etched layer of conductive material and second etched layer of conductive material are made of a metallic material that is different than the homogenous metal.

39. The semiconductor device of claim 30, wherein the first substrate and the second substrate are interconnected by at least one solder ball.
